(19) United States
(12) Patent Application Publication
(10) Pub. No.: US 2025/0218932 A1
(43) Pub. Date: Jul. 3, 2025

(54) STRAP CELLS IN SEMICONDUCTOR MEMORY DEVICES

(71) Applicant: Taiwan Semiconductor Manufacturing Company, Ltd., Hsinchu (TW)

(72) Inventors: Jui-Che Tsai, Hsinchu City (TW); Ku-Feng Lin, Hsinchu City (TW); Chia-En Huang, Hsinchu City (TW); Yih Wang, Hsinchu City (TW)

(73) Assignee: Taiwan Semiconductor Manufacturing Company, Ltd., Hsinchu (TW)

(21) Appl. No.: 18/628,513

(22) Filed: Apr. 5, 2024

Related U.S. Application Data
(60) Provisional application No. 63/616,932, filed on Jan. 2, 2024.

(51) Int. Cl. H01L 23/522; H01L 23/528; H01L 27/092; H10B 10/00

(52) U.S. Cl. CPC H01L 23/5226; H01L 23/528; H01L 23/5283; H01L 23/5286; H10B 10/12; H10B 10/18; H10D 84/853; H10D 84/854

(57) ABSTRACT

A memory device includes a first memory array disposed over a substrate, a second memory array disposed over the substrate and separated from the first memory array along a first direction, and a strap cell defined in the substrate and interposed between the first memory array and the second memory array. The strap cell includes a first boundary abutting the first memory array, a second boundary abutting the second memory array, a p-type well strap interposed between the first boundary and the second boundary along the first direction, and an n-type well strap spaced from the p-type well strap along the second direction. The first boundary and the second boundary extending along a second direction perpendicular to the first direction. The p-type well strap is coupled to a first power supply voltage, and the n-type well strap is coupled to a second power supply voltage.

### CROSS-REFERENCE TO RELATED PATENT APPLICATIONS

This application claims priority to and the benefit of U.S. Provisional Application No. 63/616,932, filed Jan. 2, 2024, titled “Memory Devices with Tap Cells,” the disclosure of which is incorporated herein by reference in its entirety for all purposes.

### BACKGROUND

As integrated circuit (IC) technologies progress towards smaller technology nodes, memory or storage cells, such as static random access memory (SRAM) cells, often incorporate transition cells, such as strap cells and filler cells, into their designs to enhance device performance, where each memory cell can store a bit of data. In one such examples, strap cells have been implemented to stabilize well potential, thereby facilitating uniform charge distribution throughout the memory cells and achieving uniform performance within an array of the memory cells. While existing designs of strap cells and filler cells have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a top view of an example block diagram of a memory block, in accordance with some embodiments.

FIG. 2 illustrates an example layout design corresponding to the example block diagram of FIG. 1, in accordance with some embodiments.

FIGS. 3A, 3B, 3C, 3D, 3E, 4A, 4B, 4C, 4D, 5 6A, 6B, 6C, 7, 8A, 8B, 8C, 9A, 9B, 9C, 10A, 10B, 10C, 11A, 11B, 11C, 12A, 12B, 12C, 13A, 13B, 13C, 14, 15A, 15B, 15C, 16, 17A, 17B, 17C, 18, 19A, 19B, 19C, 20A, 20B, 20C, 21A, 21B, 21C, 22A, 22B, 22C, 23A, 23B, 23C, and 24 each illustrate a top view of an example block diagram of a memory device including the memory block of FIGS. 1 and/or 2, in accordance with some embodiments.

FIG. 25 illustrates a flowchart of a method of manufacturing a semiconductor device, in accordance with some embodiments.

FIG. 26 illustrates a block diagram of a system of generating an IC layout design, in accordance with some embodiments.

FIG. 27 illustrates a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “couple” and “connect,” as used herein, refer to electrical or otherwise operative connection between two components with or without any intervening layers or components formed therebetween. As such, unless stated explicitly, the terms “coupled,” “connected,” “electrically coupled,” and “operatively coupled” are used interchangeably in the present disclosure.

Over the past several technology generations (or nodes), the size of transistors has been ever increasingly shrunk for delivering improvement in performance, power efficiency, and area density (PPA). Along with such a trend, design-technology co-optimization (DTCO), combined with intrinsic scaling, have been adopted to achieve the desired logic density and die cost/area reduction. As indicated by its name, DTCO refers to optimizing design and process technology together to improve performance, power efficiency, transistor density, and cost. With DTCO, the result is a robust 1.7 times increase in logic density, and a healthy 35-40% per generation chip size reduction for the same design, even when the “less-scalable” areas of the chip, such as analog and I/O are included.

DTCO for a new technology node usually involves substantial architectural innovation instead of just delivering the exact same structure as the previous generation, only smaller. As the technology nodes keep shrinking, contribution of DTCO may become increasingly significant. For example, technology affects static random access memory (SRAM) design considerations such as manufacturability, reliability, power, performance, and area. The scaling of SRAM has been one of the most fundamental and challenging issues. SRAM leakage, performance, and density are all of utmost importance and often have conflicting requirements.

With the cell arrays implemented in advanced technology nodes, it has become challenging to keep scaling down an area of the memory cell arrays with a substantial amount (e.g., greater than 5%). Transition cells, such as strap cells, edge cells, and/or filler cells, have been incorporated in memory devices to enhance the performance of the cell arrays and/or maintain device dimensions to comply with design rule check (DRC) guidelines. The present disclosure provides various memory device structures that include such transition cells on the peripheral of the memory cell arrays for improved scalability (e.g., increased chip density) of the memory devices.

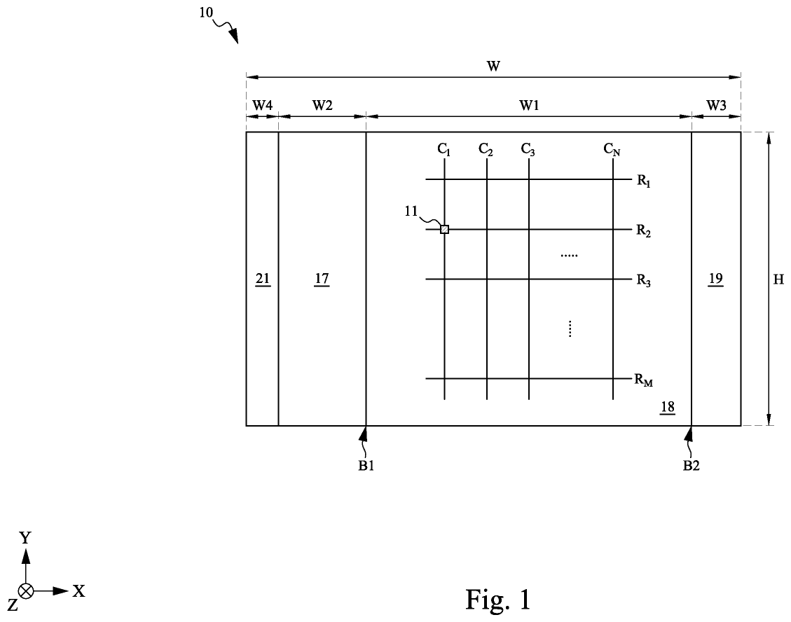

FIG. 1 illustrates an example block diagram of a semiconductor memory block 10 (hereafter referred to as a memory block 10), in accordance with various embodiments. In some embodiments, the memory block 10 is incorporated as a portion of a semiconductor memory device or macro (e.g., semiconductor memory device 100 provided herein). In the present embodiments, the memory block 10 is formed over a substrate (e.g., substrate 12) and includes at least a memory array 18 and a plurality of transition (or peripheral) cells adjacent or surrounding the memory array 18.

The memory block 10 may be included in a microprocessor, a memory cell, and/or other IC device. In some embodiments, the memory block 10 is a portion of an IC chip, a system on chip (SoC), or portion thereof, that includes various passive and active microelectronic devices, such as resistors, capacitors, inductors, diodes, p-type field effect transistors (PFETs), n-type field effect transistors (NFETs), metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof.

The memory array 18 is a hardware component that stores data. In one aspect, the memory array 18 is embodied as a semiconductor memory device. The memory array 18 includes a plurality of memory cells (or storage units) 11. The memory array 18 includes a number of rows R₁, R₂, R₃ . . . RM, each extending in a first direction (e.g., X-direction) and a number of columns C₁, C₂, C₃ . . . CN, each extending in a second direction (e.g., Y-direction). Each of the rows/columns may include one or more conductive structures. In some embodiments, each memory cell 11 is arranged in the intersection of a corresponding row and a corresponding column and can be operated according to voltages or currents through the respective conductive structures of the column and row. In the present embodiments, the memory array 18 extends a width W1 along the first direction and a height H along the second direction. The width W1 is defined between a first boundary B1 and a second boundary B2, each of which extending along the second direction.

In the present embodiments, the memory cells 11 are configured as SRAM cells, although the present disclosure may also be applicable to other types of circuits. In addition, for purposes of discussion, the memory cells 11 are each configured to include one or more transistors, such as fin field-effect transistors (FinFETs). In some examples, however, the memory cells 11 may each additionally or alternatively include other types of FETs, such as nanosheet FETs, nanowire FETs, gate-all-around (GAA) FETs, complementary FETs (CFETs), or the like.

The transition cells, which include a first strap cell 17, a second strap cell 19, and an edge cell 21, are aligned with the memory array 18 along the first direction. The first strap cell 17 and the second strap cell 19 are generally disposed along boundaries of the memory block 10 and are therefore alternatively referred to as boundary strap cells 17 and 19, respectively. Different from the memory array 18, which includes active transistors that participate in storing data for the memory device, the transition cells of the memory block 10 occupy dummy regions of the substrate separating the memory array 18 from peripheral circuits of a memory device (or macro; such as semiconductor memory device 100 described below). In the present embodiments, the first strap cell 17 abuts the memory array 18 along the first boundary B1, while the second strap cell 19 abuts the memory array 18 along the second boundary B2, such that the memory array 18 is interposed between the first strap cell 17 and the second strap cell 19. Furthermore, the edge cell 21 abuts the first strap cell 17 along a boundary of the first strap cell 17. In some embodiments, the edge cell 21 does not include any front-end device features, such as the fins 20-26, the epitaxial source/drain features 40A-40D, the gate structures 30A-30C, or the like.

In some embodiments, the transition cells are configured to enhance the performance of the memory array 18 and/or the peripheral circuits of the memory device. For example, one or both of the first strap cell 17 and the second strap cell 19 includes well straps (e.g., an n-type well strap and a p-type well strap) configured to provide protection against latch-up formed in the circuit of the memory array 18. Generally, latch-up refers to a short circuit unintentionally created between a first power supply line providing a first power supply voltage (e.g., a power supply voltage V_{DD}) and a second power supply line providing a second power supply voltage (e.g., a power supply voltage V_{SS}). By coupling a potential well (e.g., a p-type well for n-type FETs or NFETs and an n-type well for p-type FETs or PFETs) of some of the FETs in the memory array 18 to a corresponding power supply rail using a well strap, the latch-up phenomenon associated with the FETs can be mitigated.

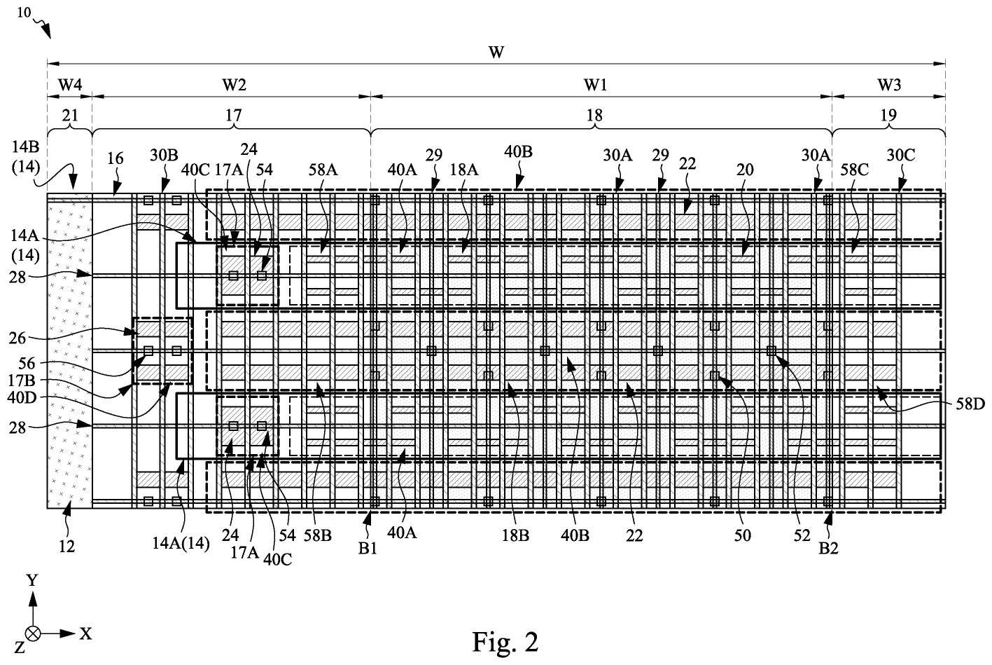

For example, using an n-type well strap (or an n-well tap, NTAP; e.g., an n-type well strap 17A of FIG. 2) to couple an n-type well provided in the first strap cell 17 to the first power supply voltage can help reduce latch-up of p-type FETs (PFETs) in the memory array 18. Similarly, using a p-type well strap (or a p-well tap, PTAP; e.g., a p-type well strap 17B of FIG. 2) to couple a p-type well provided in the first strap cell 17 to the second power supply voltage can help reduce latch-up of n-type FETs (NFETs) in the memory array 18. In some embodiments, each of the first strap cell 17 and the second strap cell 19 further includes a plurality of dummy FETs (as opposed to active transistors in the memory array 18) configured to stabilize well potential near the first boundary B1 and the second boundary B2, which may help facilitate uniform charge distribution throughout the memory array 18 (e.g., between edge memory cells and inner memory cells) and thus achieve uniform performance among the memory cells 11 of the memory array. In some embodiments, only one of the first strap cell 17 and the second strap cell 19 includes the n-type well straps and the p-type well straps, i.e., are coupled to the first power supply voltage and the second power supply voltage. For example, in the depicted embodiments, only the first strap cell 17 is electrically coupled to the first supply voltage and the second supply voltage via the n-type well straps and the p-type well straps, respectively, and the second strap cell 19 is electrically isolated from the first supply voltage and the second supply voltage.

In some embodiments, the transition cells are configured to maintain a certain width-to-height ratio of the memory block 10 according to DRC constraints for a given memory device. For example, the edge cell 21 is generally disposed at an outer edge of the memory device along the second direction and configured with a dimension (e.g., a width along the first direction) to ensure a consistent width-to-height ratio of the memory block 10 according to DRC constraints at a given technology node. The edge cell 21 generally does not include any active or dummy devices (e.g., FETs) but may include a doped region, such as the n-type doped region 14B. In some embodiments, dimensions (e.g., widths along the first direction) of one or both of the first strap cell 17 and the second strap cell 19 are also configured to maintain a given width-to-height ratio for the memory block 10 according to certain DRC constraints.

As depicted herein, still referring to FIG. 1, the memory block 10 extends a width W along the first direction (e.g., X-direction), which accounts for a width W1 of the memory array 18, a width W2 of the first strap cell 17, a width W3 of the second strap cell 19, and width W4 of the edge cell 21. In the present embodiments, the width W1 is greater than each of the widths W2, W3, and W4, and the width W4 is less than each of the widths W1, W2, and W3. For embodiments in which the first strap cell 17 includes the n-type well straps and the p-type well straps and the second strap cell 19 is free of any of the n-type well straps and the p-type well straps, the width W2 is greater than the width W3. Using contacted poly pitch (CPP) as a measuring unit, the widths W1, W2, W3, and W4 can each be measured as one or multiples of CPPs. For example, the width W2 may be 10 CPP, the width W3 may be 4 CPP, and the width W4 may be 1.5 CPP.

While existing DTCO techniques for improving the manufacturability, reliability, power, performance, and area of memory (e.g., SRAM) devices have generally been adequate, they are not entirely satisfactory in all aspects. The present disclosure provides various embodiments directed to structures and arrangement of the transition cells in the peripheral of the memory array 18 for improved scalability of the memory devices. In various embodiments, the present disclosure contemplates placement of two adjacent memory blocks 10, as well as memory devices that include such memory blocks 10, to consolidate one or more of the first strap cell 17, the second strap cell 19, and the edge cell 21 between the memory blocks 10, leading to a reduction in the width (e.g., the width W) of the memory blocks 10 for improved scalability.

FIG. 2 illustrates an example layout of the memory block 10, in portion or entirety, according to various embodiments of the present disclosure. The components of the memory block 10 are arranged in a configuration substantially similar to that depicted in FIG. 1. For example, the edge cell 21, the first strap cell 17, the memory array 18, and the second strap cell 19 are arranged along the first direction and disposed over a substrate 12. The substrate 12 may include any suitable semiconductor material, such as an elementary semiconductor (e.g., silicon and/or germanium), a compound semiconductor (e.g., silicon carbide, silicon phosphide, gallium arsenide, gallium phosphide, indium phosphide, indium arsenide, and/or indium antimonide), an alloy semiconductor (e.g., SiGe, SiPC, GaAsP, AlInAs, AlGaAs, GaInAs, GaInP, and/or GaInAsP). Alternatively, the substrate 12 may be a semiconductor-on-insulator substrate, such as a silicon-on-insulator (SOI) substrate. In some embodiments, the substrate 12 includes a p-type dopant, such as boron (for example, BF₂), indium, other p-type dopants, or combinations thereof, and is therefore considered a p-substrate.

In the present embodiments, the substrate 12 includes various doped regions configured according to design requirements of memory block 10. In the depicted embodiment, the substrate 12 includes a plurality of n-type doped regions 14A and 14B, collectively referred to as n-type doped regions 14 (also referred to as n-wells 14), and a p-type doped region 16 (also referred to as a p-well 16). In the depicted embodiment, the n-type doped regions 14A each extend across the first strap cell 17, the memory array 18, and the second strap cell 19, while the n-type doped region 14B is disposed (or defined) within the edge cell 21. In some embodiments, the p-type doped region 16 surrounds the n-type doped regions 14. N-type doped regions 14 are configured for a plurality of p-type metal-oxide-semiconductor (PMOS) FinFETs 18A, such as pull-up (PU) FinFETs, and p-type doped region 16 is configured for a plurality of n-type MOS (NMOS) FinFETs 18B, such as pull-down (PD) FinFETs, such that the memory array 18 includes a plurality of CMOS FinFETs. The PMOS FinFETs 18A and the NMOS FinFETs 18B are spaced from each other along the second direction.

N-type doped regions, such as n-type doped region 14, are doped with n-type dopants, such as phosphorus, arsenic, other n-type dopant, or combinations thereof. P-type doped regions, such as p-type doped region 16, are doped with p-type dopants, such as boron (for example, BF₂), indium, other p-type dopant, or combinations thereof. In some embodiments, substrate 12 includes doped regions formed with a combination of p-type dopants and n-type dopants. The various doped regions can be formed directly on and/or in substrate 12, for example, providing a p-well structure, an n-well structure, a dual-well structure, a raised structure, or combinations thereof. An ion implantation process, a diffusion process, and/or other suitable doping process can be performed to form the various doped regions.

In the depicted embodiment, the n-type well strap 17A is disposed over (and electrically coupled to) each of the n-type doped regions 14A. The n-type well strap 17A is configured to electrically couple each of the n-type doped regions 14A to the first power supply voltage, such as a power supply voltage V_{DD}. The p-type well strap 17B is disposed over (and electrically coupled to) the p-type doped region 16. The p-type well strap 17B is configured to electrically couple the p-type doped region 16 to a second power supply voltage, such as a power supply voltage V_{SS}. In some embodiments, the power supply voltage V_{DD} is a positive power supply voltage, and the power supply voltage V_{SS} is an electrical ground.

The memory block 10 includes various fins disposed over substrate 12, such as fins 20, 22, 24, and 26 disposed over substrate 12. The fins 20-26 each extend lengthwise along the first direction (e.g., X-direction) across at least a portion of the memory block 10 and are spaced apart from one another (e.g., parallel to one another) along the second direction (e.g., Y-direction). In some embodiments, the PMOS FinFETs 18A include fins 20 disposed over (and electrically coupled to) the n-type doped regions 14A, the NMOS FinFETs 18B include fins 22 disposed over (and electrically coupled to) the p-type doped region 16, the n-type well straps 17A each include a fin 24 disposed over (and electrically coupled to) the n-type doped region 14A, and the p-type well strap 17B includes a fin 26 disposed over (and electrically coupled to) p-type doped region 16. The present disclosure contemplates embodiments where the PMOS FinFET 18A, the NMOS FinFET 18B, the n-type well strap 17A, and/or the p-type well strap 17B each include more or less fins. In some embodiments, to enhance performance of memory block 10, a dopant concentration of the FinFET fins, i.e., the fins 20 and 22, is less than a doping concentration of the well strap fins, i.e., the fins 24 and 26.

Though not depicted, isolation features are formed over and/or in substrate 12 to isolate various regions, such as various device regions, of the memory block 10. For example, the isolation features separate and isolate active device regions and/or passive device regions from each other, such as the PMOS FinFET 18A, the NMOS FinFET 18B, the n-type well strap 17A, and the p-type well strap 17B. The isolation features further separate and isolate the fins, such as the fins 20-26, from one another. In some embodiments, the isolation features surround a bottom portion of each of the fins 20-26. The isolation features may include any suitable dielectric material, such as silicon oxide, silicon nitride, silicon oxynitride, the like, or combinations thereof. The isolation features may include different structures, such as shallow trench isolation (STI) structures, deep trench isolation (DTI) structures, and/or local oxidation of silicon (LOCOS) structures.

In the depicted embodiment, the first strap cell 17 includes a plurality of PMOS dummy FETs 58A and a plurality of NMOS dummy FETs 58B. The PMOS dummy FETs 58A include end portions of the fins 20 disposed over (and electrically coupled to) the n-type doped regions 14A. The NMOS dummy FETs 58B include end portions of the fins 22 disposed over (and electrically coupled to) the p-type doped region 16. In this regard, the PMOS dummy FETs. 58A are disposed between the n-type well strap 17A and the memory array 18 (including the PMOS FinFETs 18A), and the NMOS dummy FETs 58B are disposed between the p-type well strap 17B and the memory array 18 (including the NMOS FinFETs 18B). As described above, the PMOS dummy FETs 58A and the NMOS dummy FETs 58B may be configured to stabilize well potential near the first boundary B1, which may help facilitate uniform charge distribution throughout the memory array 18. Similarly, the second strap cell 19 may also include PMOS dummy FETs 58C and NMOS dummy FETs 58D. In some embodiments, each PMOS dummy FET 58A and 58C includes a gate terminal (e.g., provided by gate structures 30B and 30C, respectively) that is electrically coupled to a power supply voltage (e.g., the first power supply voltage V_{DD}) rather than a signal voltage. Similarly, each NMOS dummy FET 58B and 58D includes a gate terminal that is electrically coupled to a power supply voltage (e.g., the second power supply voltage V_{SS}) rather than a signal voltage.

The fins 20-26 each have at least one channel region, at least one source region, and at least one drain region defined lengthwise along the first direction, where a channel region is disposed between the source region and the drain region (generally referred to as source/drain regions). Channel regions include a top portion defined between sidewall portions, where the top portion and the sidewall portions engage with a gate structure, such that current can flow between the source/drain regions during operation. The source/drain regions can also include top portions defined between sidewall portions. The fins 20 of the PMOS FinFETs 18A are oriented substantially parallel to one another, and the fins 22 of the NMOS FinFETs 18B are oriented substantially parallel to one another.

Various gate structures 30A, 30B, and 30C, collectively referred to as gate structures 30, are disposed over the fins 22-26, where each gate structure 30 extends along the second direction, i.e., perpendicular to each of the fins 22-26. In the depicted embodiment, the gate structures 30A are each disposed over and engage the respective channel regions of the fins 20 and 22 in the memory array 18; the gate structures 30B are each disposed over and engage the respective channel regions of the fins 20-26 in the first strap cell 17; and the gate structures 30C are each disposed over and engage the respective channel regions of the fins 20 and 22 in the second strap cell 19. In some embodiments, the gate structures 30A-30C each wrap respective channel regions of fins 20-26, thereby interposing respective source/drain regions of fins 20-26 and allowing current to flow therebetween.

In some embodiments, the gate structures 30A are active gate structures, whereas the gate structures 30B and 30C are dummy gate structures. “Active gate structure” generally refers to an electrically functional gate structure, whereas “dummy gate structure” generally refers to an electrically non-functional gate structure. In some embodiments, a dummy gate structure mimics physical properties of an active gate structure, such as physical dimensions of the active gate structure, yet is electrically inoperable (in other words, does not enable current to flow between source/drain regions) in the memory block 10. In some embodiments, the gate structures 30B and 30C enable a substantially uniform processing environment, for example, enabling uniform epitaxial material growth in source/drain regions of the fins 20-26 (for example, when forming epitaxial source/drain features), uniform etch rates in source/drain regions of the fins 20-26 (for example, when forming source/drain recesses), and/or uniform, substantially planar surfaces (for example, by reducing (or preventing) processing (e.g., chemical-mechanical polishing, or CMP)-induced dishing effects).

Epitaxial source features and epitaxial drain features, collectively, referred to as epitaxial source/drain features, are disposed over the source/drain regions of the fins 20-26. For example, semiconductor material is epitaxially grown on the fins 20-26, forming epitaxial source/drain features 40A, 40B, 40C, and 40D, respectively. In the depicted embodiment, a fin recess process (for example, an etch back process) is performed in source/drain regions of the fins 20-26, such that the epitaxial source/drain features 40A-40D are grown from lower fin active regions of the fins 20-26. In some embodiments, source/drain regions of the fins 20-26 are not subjected to a fin recess process, such that epitaxial source/drain features 40A-40D are grown from and wrap at least a portion of upper fin active regions of the fins 20-26. In furtherance of the depicted embodiment, the epitaxial source/drain features 40A-40D extend (or grow) laterally along the first direction (in some embodiments, substantially perpendicular to the fins 20-26), such that the epitaxial source/drain features 40A-40D are merged epitaxial source/drain features that span more than one fin.

An epitaxy process can implement CVD deposition techniques (for example, vapor-phase epitaxy (VPE), ultra-high vacuum CVD (UHV-CVD), LPCVD, and/or PECVD), molecular beam epitaxy, other suitable SEG processes, or combinations thereof. The epitaxy process can use gaseous and/or liquid precursors, which interact with the composition of the fins 20-26. The epitaxial source/drain features 40A-40D are doped with n-type dopants and/or p-type dopants. In the depicted embodiment, the epitaxial source/drain features 40A include a p-type doped epitaxial material and form the PMOS FinFETs 18A; the epitaxial source/drain features 40B include an n-type doped epitaxial material and form the NMOS FinFETs 18B; the epitaxial source/drain features 40C include an n-type doped epitaxial material; and the epitaxial source/drain features 40D include a p-type doped epitaxial material. In this regard, the n-type well strap 17A and the NMOS FinFET 18B include dopants of the same conductivity type, the p-type well strap 17B and the PMOS FinFET 18A include dopants of the same conductivity type, and the n-type well strap 17A and the p-type well strap 17B include dopants of different (or opposite) conductivity types.

For example, for the PMOS FinFET 18A and the p-type well strap 17B, the epitaxial source/drain features 40A and 40D are epitaxial layers including silicon and/or germanium, where the silicon germanium containing epitaxial layers are doped with boron, carbon, other p-type dopant, or combinations thereof (for example, forming a Si:Ge:B epitaxial layer or a Si:Ge:C epitaxial layer). In furtherance of the example, for the NMOS FinFET 18B and the n-type well strap 17A, the epitaxial source/drain features 40B and 40C are epitaxial layers including silicon and/or carbon, where silicon-containing epitaxial layers or silicon-carbon-containing epitaxial layers are doped with phosphorous, arsenic, other n-type dopant, or combinations thereof (for example, forming a Si:P epitaxial layer, a Si:C epitaxial layer, or a Si:C:P epitaxial layer).

In some embodiments, the epitaxial source/drain features 40A-40D include materials and/or dopants that achieve desired tensile stress and/or compressive stress in the channel region. In some embodiments, the epitaxial source/drain features 40A-40D are doped during deposition by adding impurities to a source material of the epitaxy process. In some embodiments, the epitaxial source/drain features 40A-40D are doped by an ion implantation process subsequent to a deposition process. In some embodiments, annealing processes are performed to activate dopants in epitaxial source/drain features 40A-40D and/or other source/drain regions in the memory block 10. In some embodiments, silicide layers are formed on epitaxial source/drain features 40A-40D by any suitable method. In some embodiments, the silicide layers include nickel silicide, titanium silicide, or cobalt silicide. In some embodiments, the silicide layers and epitaxial source/drain features 40A-40D are collectively referred to as the epitaxial source/drain features.

A multilayer interconnect (MLI) feature, including a combination of dielectric layers and electrically conductive layers (for example, metal layers) configured to form various interconnect structures, is disposed over the substrate 12, covering the components of the memory block 10 in portions or in entirety. MLI feature electrically couples various devices (for example, the PMOS FinFET 18A, the NMOS FinFET 18B, the n-type well strap 17A, the p-type well strap 17B, transistors, resistors, capacitors, and/or inductors) and/or components (for example, the gate structures 30A-30C) and/or source/drain features (for example, epitaxial source/drain features 40A-40D), such that the various devices and/or com-ponents can operate as specified by design requirements of the memory block 10. The conductive layers are configured to form vertical interconnect features, such as device-level contacts and/or vias, and/or horizontal interconnect features, such as conductive lines. Vertical interconnect features typically connect horizontal interconnect features in different layers (or different planes) of MLI feature. During operation of the memory block 10, the interconnect features are configured to route signals between the devices and/or the components of memory block 10 and/or distribute signals (for example, clock signals, voltage signals, and/or ground signals) to the devices and/or the components of memory block 10.

In order to depict the various well straps defined in the substrate 12, the components of the MLI feature of the memory block 10 are largely omitted in FIG. 2 with the exception of vias 50, 52, 54, and 56. The vias 50-56 are disposed in one or more of interlayer dielectric (ILD) layers (not depicted) to form interconnect structures. In some embodiments, the vias 50-56 electrically couple and/or physically couple conductive features of the MLI feature to one another as well as to underlying device-level features (for example, the gate structures 30A-30C and/or the epitaxial source/drain features 40A-40D). In the depicted embodiment, the vias 50 and 52 are respectively disposed on the device-level contacts (not depicted) coupled to the epitaxial source/drain features 40B (i.e., the NMOS FinFETs 18B), for example, such that the vias 50 and 52 physically (or directly) connect the device-level contacts (for example, gate contacts and source/drain contacts) respectively to conductive lines (not depicted) subsequently formed over the vias 50 and 52.

In the present embodiments, the vias 50 and 52 electrically couple the epitaxial source/drain features 40B of the NMOS FinFETs 18B respectively to a conductive line that is is electrically connected to the second power supply voltage V_{SS}. In some embodiments, the second power supply voltage V_{SS} is configured as ground and/or a negative supply voltage. Though not depicted, the memory block 10 may include a plurality of additional vias electrically coupled to the device-level features (or contacts). For example, the memory block 10 may include vias electrically coupled to gate contacts of the gate structures 30A and/or to source/drain contacts of the epitaxial source/drain features 40A. In the present embodiments, the vias 54 electrically couple the epitaxial source/drain features 40C of the n-type well strap 17A to a conductive line (not depicted) that is electrically connected to the first power supply voltage V_{DD}. Furthermore, the vias 56 electrically couple the epitaxial source/drain feature 40D of the p-type well strap 17B to a conductive line (not depicted) that is electrically connected to the second power supply voltage V_{SS}.

The vias 50-56 include any suitable electrically conductive material, such as Ta, Ti, Al, Cu, Co, W, TiN, TaN, other suitable conductive materials, or combinations thereof. Various conductive materials can be combined to provide the vias 50-56, such as a barrier layer, an adhesion layer, a liner layer, a bulk layer, other suitable layer, or combinations thereof. The vias 50-56 may be formed by any suitable method, such as patterning the corresponding ILD layers by lithography processes and/or etching processes to form openings (trenches), which are subsequently filled with one or more conductive materials. The conductive material(s) can be deposited by PVD, CVD, ALD, electroplating, electroless plating, other suitable deposition process, or combinations thereof. Thereafter, any excess conductive material(s) can be removed by a planarization process, such as a CMP process, thereby planarizing top surfaces of ILD layers and the vias 50-56.

In some embodiments, the memory block 10 further includes a plurality of horizontal isolation structures 28 and vertical isolation structures 29 each extending at least across the first strap cell 17, the memory array 18, and the second strap cell 19. The horizontal isolation structures 28 and the vertical isolation structures 29 may each include a suitable dielectric material, such as silicon oxide, silicon nitride, silicon oxynitride, the like, or combinations thereof. In some embodiments, two adjacent horizontal isolation structures 28 define half of a height of the memory cell 11 (e.g., corresponding to one inverter), and two adjacent vertical isolation structures 29 define a width of each memory cell 11. For example, in the depicted embodiment, the width of each memory cell 11 defined by two adjacent vertical isolation structures 29 is equivalent to 2 CPP.

In the present disclosure, various embodiments directed to structures and arrangement of one or more transition cells (e.g., the first strap cell 17, the second strap cell 19, and/or the edge cell 21) in the peripheral of a memory array (e.g., the memory array 18) of a memory device are contemplated to improve the scalability of the memory devices. In various embodiments, the present disclosure contemplates placement of two adjacent memory blocks (e.g., the memory block 10), as well as memory devices that include such memory blocks, for the reduction in the width of two adjoined memory blocks (or devices) for improved scalability. For example, in existing implementations, a plurality of memory blocks 10 are arranged by abutting the edge cell 21 of a first memory block 10 with the edge cell 21 of a second memory block 10 such that the two edge cells 21 are positioned side-by-side along the first direction (e.g., X-direction). In this regard, a total width of the two abutted memory blocks 10 is equivalent to 2*W, where the width W is the sum of the widths W2, W3, and W4 as depicted in FIGS. 1 and 2. In the present embodiments, at least one of the transition cells described herein may be consolidated to reduce the width W of each memory block 10, leading to a more compact layout design towards greater scalability.

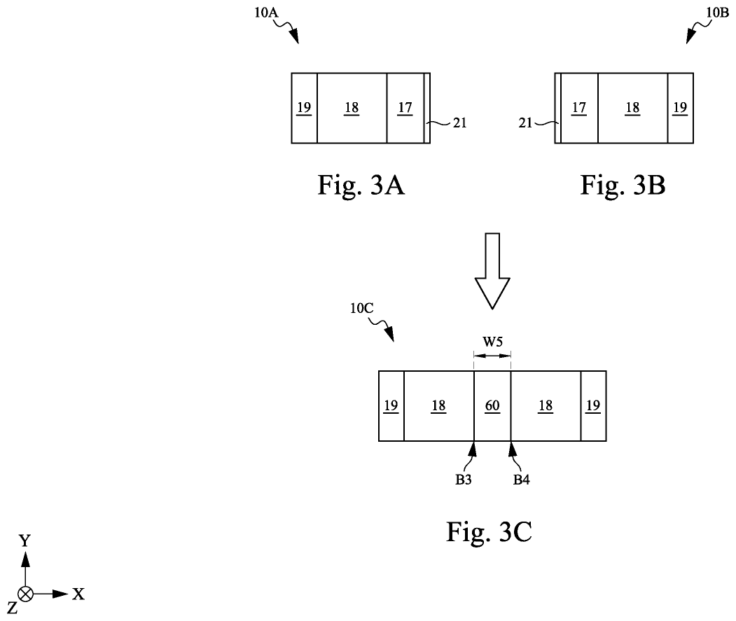

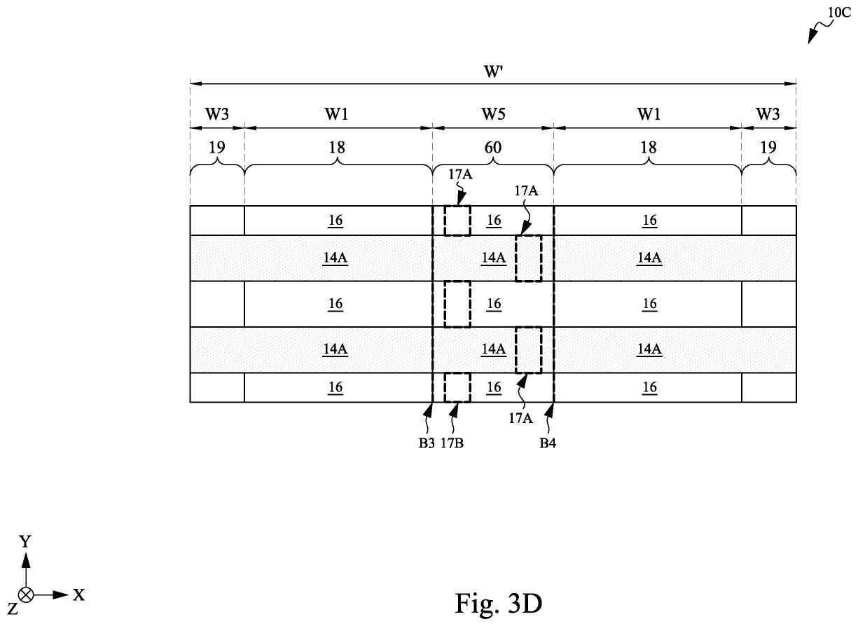

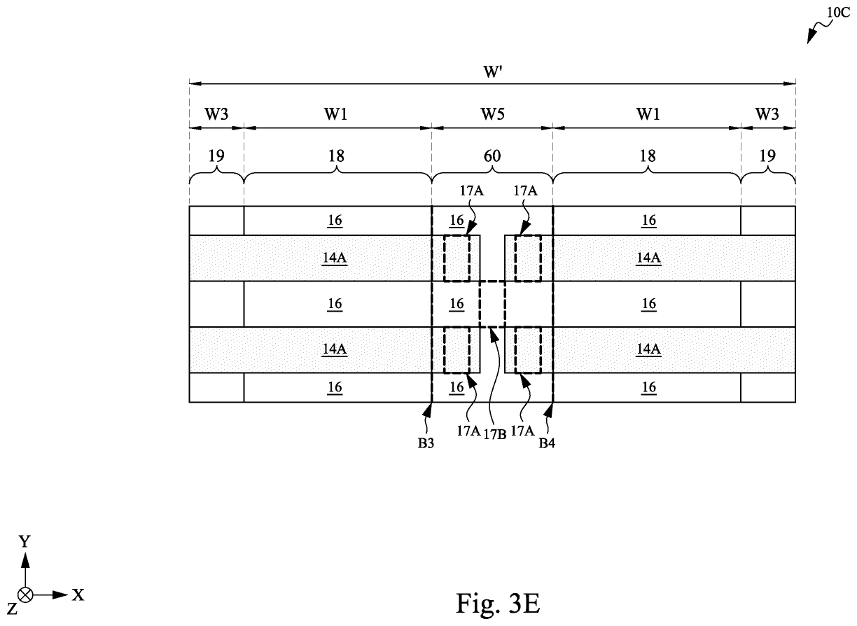

In some embodiments, referring to FIGS. 3A-3C collectively, a first memory block 10A and a second memory block 10B, each of which is equivalent to the first memory block 10 described herein, are adjoined (or coupled, merged, etc.) to one another by placing two (e.g., a first and a second) edge cells 21 in a side-by-side configuration along the first direction and consolidating (or merging) the adjoined edge cells 21 and their respectively adjacent (e.g., a first and a second) first strap cells 17. The resulting adjoined memory block 10C includes a third strap cell 60 interposed between the two (e.g., a first and a second) memory arrays 18, where the third strap cell 60 has a width W5 that spans across a region defined by a first boundary B3 and a second boundary B4 each extending along the second direction. In this regard, the first boundary B3 abuts the memory array 18 of the first memory block 10A and the second boundary B4 abuts the memory array 18 of the second memory block 10B. As depicted herein, the memory blocks 10A and 10B are arranged as mirror images of one another about the third strap cell 60. Notably, the adjoined memory block 10C no longer includes any edge cell 21, which is free of any FETs (e.g., front-end device features) and well straps as described in detail above with respect to FIG. 2. Instead, the adjoined memory block 10C includes the third strap cell 60 that consolidates the structures and functions of two of the first strap cells 17 from two adjoined memory blocks 10A and 10B.

Specifically, referring to FIG. 3D, which illustrates details of an embodiment of the adjoined memory block 10C, consolidating the two edge cells 21 and the two adjacent first strap cells 17 includes forming each n-type doped region 14A and each p-type doped region 16 to laterally extend between at least the two memory arrays 18 (and the two second strap cells 19 in the depicted embodiments) and across the third strap cell 60 along the first direction. In the present embodiments, the third strap cell 60 includes alternating arrangement of the n-type doped region 14A and the p-type doped region 16 along the second direction, where each doped region includes a corresponding well strap. For example, the n-type doped region 14A includes the n-type well strap 17A, which is electrically coupled to the first power supply voltage V_{DD}, and each p-type doped region 16 includes the p-type well strap 17B, which is electrically coupled to the second power supply voltage V_{SS}, as depicted in FIG. 2 and described in detail above. Accordingly, the n-type well strap 17A and the p-type well strap 17B are collectively interposed between the two memory arrays 18. Furthermore, the n-type well strap 17A and the p-type well strap 17B are also arranged in an alternating pattern along the second direction in the third strap cell 60, which is interposed between the two memory arrays 18 along the first direction. In some embodiments, the n-type well strap(s) 17A and the p-type well strap 17B are offset along the first direction as depicted in FIG. 3D.

Alternatively, referring to FIG. 3E, which illustrates details of another embodiment of the adjoined memory block 10C, the n-type doped region 14A of each of the memory blocks extends partially into the third strap cell 60 such that a portion of the p-type doped region 16 extends continuously between portions of the n-type doped region 14A in the third strap cell 60. As such, each portion of the n-type doped region 14A in the third strap cell 60 includes the n-type well strap 17A, and the portion of the p-type doped region 16 in the third strap cell 60 includes one common p-type well strap 17B, which electrically couples portions of the p-type doped region 16 in the memory arrays 18 with the second power supply voltage V_{SS}.

Though not depicted in FIGS. 3A-3E, the adjoined memory block 10C includes features similar to (or the same as) those of the memory block 10 as described in detail above. For example, the adjoined memory block 10C further includes (e.g., a first and a second) second strap cells 19 disposed adjacent to each memory array 18. Each memory array 18 (in each of the memory blocks 10A and 10B) includes a plurality of PMOS FinFETs 18A disposed in the n-type doped region 14A and a plurality of NMOS FinFETs 18B disposed in the p-type doped region 16. Furthermore, the third strap cell 60 includes at least a first via configured to electrically couple each n-type well strap 17A to the first power supply voltage V_{DD} and a second via configured to couple each p-type well strap 17B to the second power supply voltage V_{SS}.

In some embodiments, the third strap cell 60 further includes a plurality of dummy FETs (as opposed to the active FETs in the memory arrays 18) similar to the first strap cell 17 of the memory block 10 described above. For example, the third strap cell 60 may each include the PMOS dummy FETs 58A disposed between the n-type well strap 17A and the PMOS FinFETs 18A in the n-type doped region 14A and a plurality of NMOS dummy FETs 58B disposed between the p-type well strap 17B and the NMOS FinFETs 18B in the p-type doped region 16. Similarly, each second strap cell 19 may include the PMOS dummy FETs 58C and the NMOS dummy FETs 58D, as described in detail above.

In existing implementations, adjoining the memory blocks 10A and 10B to form the depicted configuration would generally result in the width W5 of the third strap cell 60 to be equivalent to 2*(W2+W4), where the width W2 is that of the first strap cell 17 and the width W4 is that of the edge cell 21, and where the width W2 is greater than the width W3 of the second strap cell 19, according to descriptions of FIGS. 1 and 2. However, in the present embodiments (see FIGS. 3A-3E), by removing the edge cell 21 of each memory block, which is generally provided as a means to adjust the overall width of the memory block in accordance with the DRC constraints, the width W5 can be reduced by at least 2*W4. In addition, forming the third strap cell 60 consolidates two adjacent first strap cells 17, which may further reduce the width W5 to be in a range of greater than or equal to W2 to less than 2*W2. For example, if the width W2 of the first strap cell 17 is 10 CPP, then the width W5 of the third strap cell 60 is at least 10 CPP and less than 20 CPP, such as 10 CPP, 14 CPP, or 17 CPP, etc. In some embodiments, the specific value of the width W5 in the range of W2 to 2*W2 varies based on the specific width-to-height ratio in accordance with the DRC constraints of a given technology node. For example, a width-to-height ratio may be defined as a multiple of one CPP. In this regard, the overall dimension, such as a width W′ of the adjoined memory block 10C, is defined as 2*(W1+W3)+W5, which is less than 2*W as defined herein.

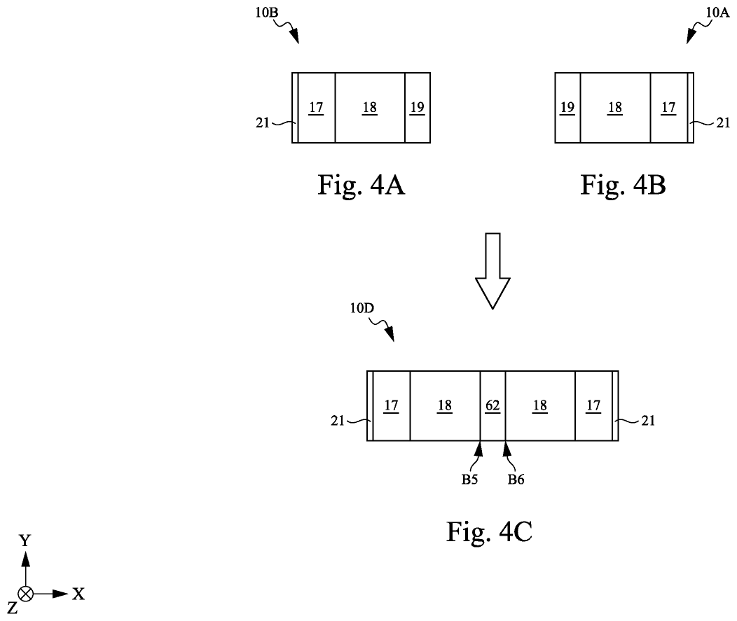

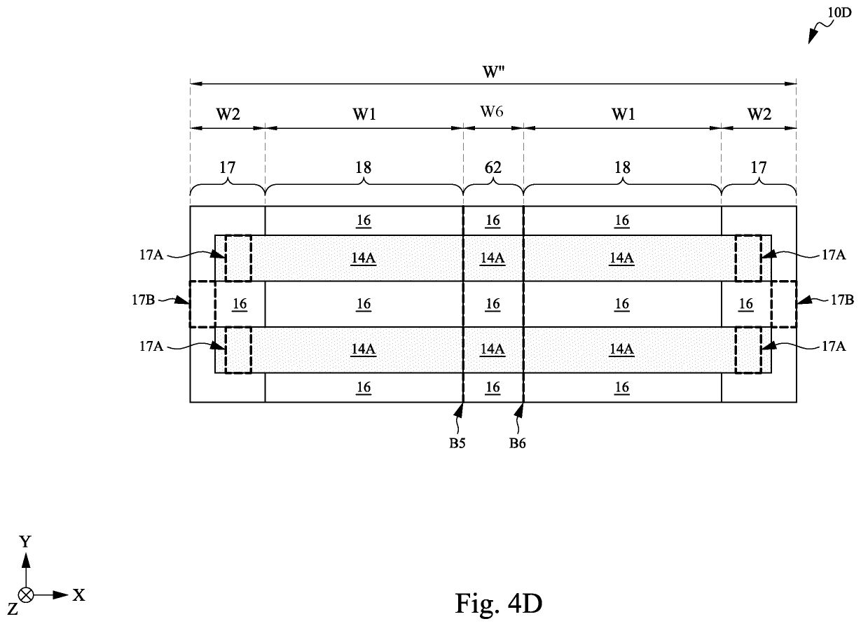

In some embodiments, referring to FIGS. 4A-4D collectively, the first memory block 10A and the second memory block 10B are adjoined (or coupled) to one another by placing the two (e.g., a first and a second) second strap cells 19 in a side-by-side configuration along the first direction and consolidating (or merging) the adjoined second strap cells 19. The resulting adjoined memory block 10D includes a fourth strap cell 62 interposed between the two (e.g., a first and a second) memory arrays 18, where the fourth strap cell 62 has a width W6 that spans across a region defined by a first boundary B5 and a second boundary B6 each extending along the second direction. In this regard, the first boundary B5 abuts the memory array 18 of the first memory block 10A and the second boundary B6 abuts the memory array 18 of the second memory block 10B. Analogous to the adjoined memory block 10C, the adjoined memory block 10D includes the fourth strap cell 62 that consolidates the structures and functions of two of the second strap cells 19 from two neighboring memory blocks into a single strap cell, i.e., the fourth strap cell 62. In some embodiments, the adjoined memory block 10D includes the edge cells 21 as depicted in FIG. 4C. Alternatively, the adjoined memory block 10D can be merged with another memory block, such as the first memory block 10A, by adjoining two first strap cells 17 and removing one of the edge cells 21 in a manner similar to that described above with respect to FIGS. 3A-3E.

FIG. 4D illustrates an embodiment of the adjoined memory block 10D. In some embodiments, consolidating the two second strap cells 19 includes forming each n-type doped region 14A and each p-type doped region 16 to laterally extend between at least the two memory arrays 18 and across the fourth strap cell 62 along the first direction. Further, each n-type doped region 14A partially extends into each first strap cell 17 adjoining each memory array 18 and opposing the fourth strap cell 62 along the first direction. In the present embodiments, similar to the adjoined memory block 10C, the fourth strap cell 62 includes alternating arrangement of the n-type doped region 14A and the p-type doped region 16 along the second direction. However, different from the adjoined memory block 10C, the fourth strap cell 62 is free of any well strap that is electrically coupled to the any of the power supply voltage (V_{DD} or V_{SS}). Instead, the n-type well strap(s) 17A, which is electrically coupled to the first power supply voltage V_{DD}, and the p-type well strap 17B, which is electrically coupled to the second power supply voltage V_{SS}, are disposed in the first strap cell 17 of each of the memory blocks 10A and 10B such that the n-type well strap(s) 17A and the p-type well strap 17B are disposed along a side of the memory array 18 opposite to the fourth strap cell 62. Other aspects of the adjoined memory block 10D are similar to (or substantially the same as) those of the memory block 10 and their descriptions are therefore not repeated herein. Furthermore, due to their positions within the memory device, the third strap cell 60 and the fourth strap cell 62 may be alternatively referred to as consolidated (or center) strap cells, as opposed to boundary strap cells, such as the first strap cell 17 and the second strap cell 19.

Similar to the adjoined memory block 10C, adjoining the memory blocks 10A and 10B to form the depicted configuration would generally result in the width W6 of the fourth strap cell 62 to be equivalent to 2*W3, where the width W3 is that of the second strap cell 19, and where the width W3 is less than the width W2 of the first strap cell 17, according to descriptions of FIGS. 1 and 2. However, in the present embodiments (see FIGS. 4A-4D), by consolidating (or merging) two second strap cells 19 into the fourth strap cell 62, the width W6 can be reduced by at least an equivalent of the width W3. As such, the width W6 is greater than or equal to the width W3 and less than the width 2*W3. For example, if the width W3 of the second strap cell 19 is 4 CPP, then the width W6 of the fourth strap cell 62 is at least 4 CPP and less than 8 CPP, such as 4 CPP, 5 CPP, or 6.5 CPP, etc. In some embodiments, the specific value of the width W6 in the range of W3 and 2*W3 varies based on the specific width-to-height ratio in accordance with the DRC constraints of a given technology node, similar to the determination of the width W5. In this regard, the overall dimension, such as a width W″ of the adjoined memory block 10D, is defined as 2*(W1+W2)+W6, which is less than 2*W as defined herein.

In some embodiments, the adjoined memory block 10C and the adjoined memory block 10D are each configured as a portion of a memory device that also includes a plurality of peripheral circuit components disposed above, below, or laterally adjacent to components of the adjoined memory block 10C and the adjoined memory block 10D. In some embodiments, additional memory blocks (e.g., the memory block 10A/10B) are merged with the adjoined memory block 10C or the adjoined memory block 10D in manner similar to those described above with respect to forming the third strap cell 60 or the fourth strap cell 62, respectively.

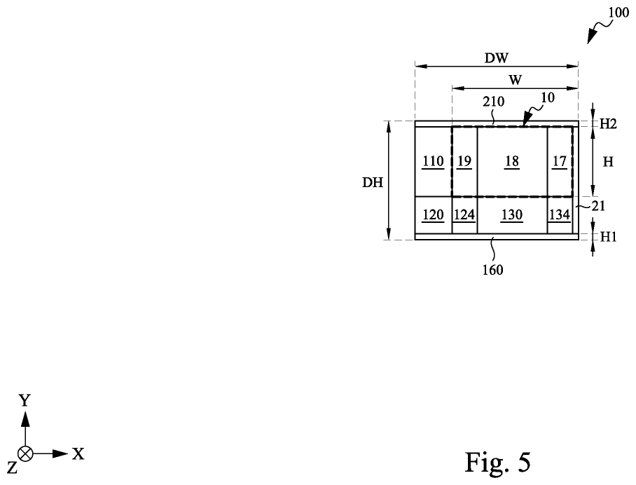

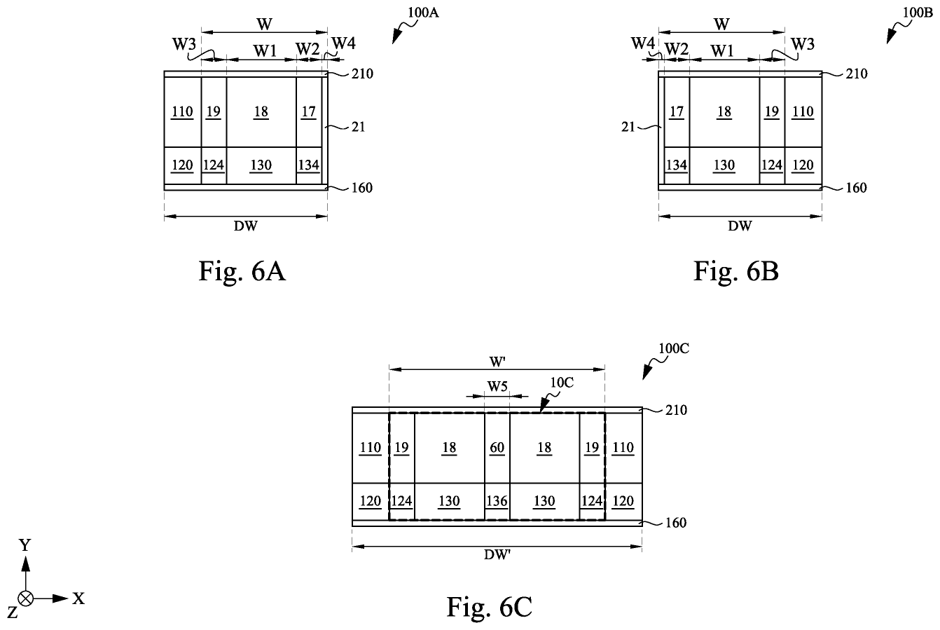

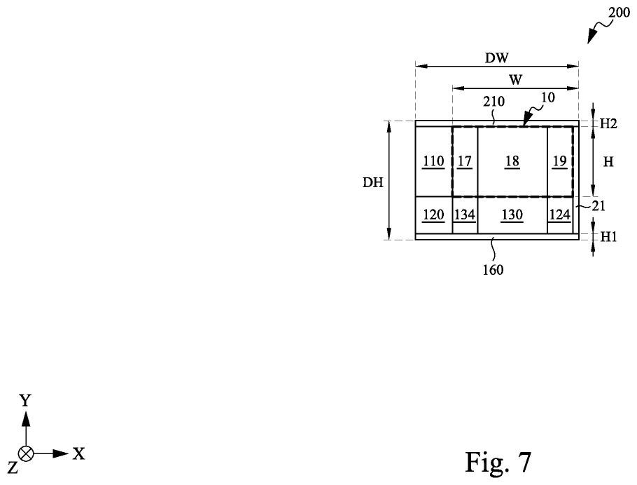

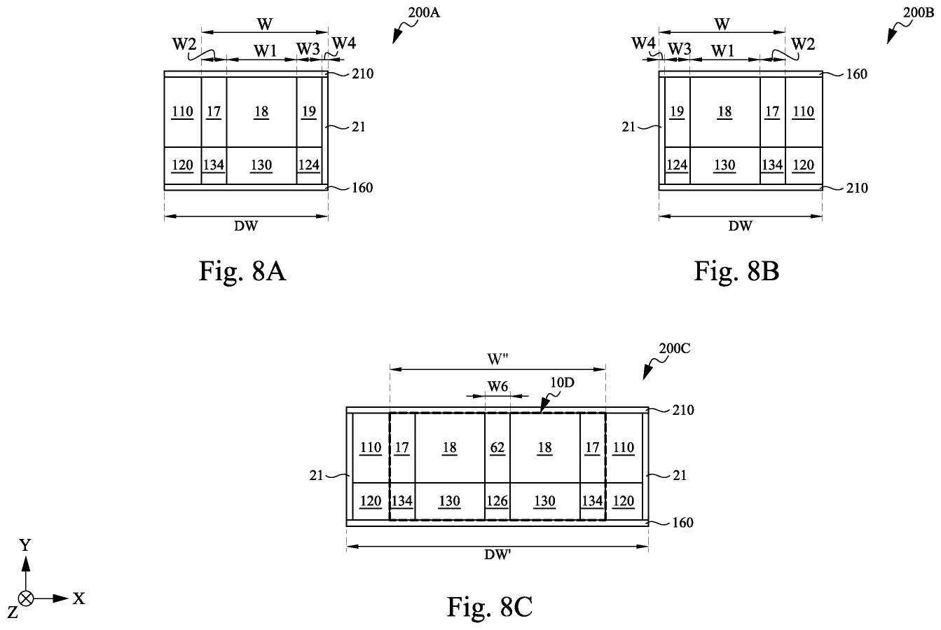

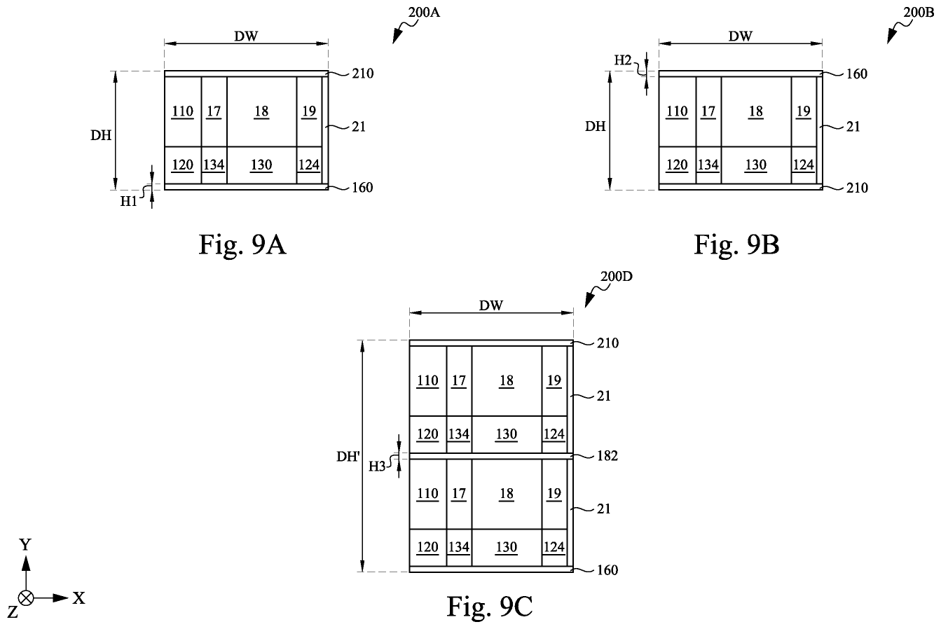

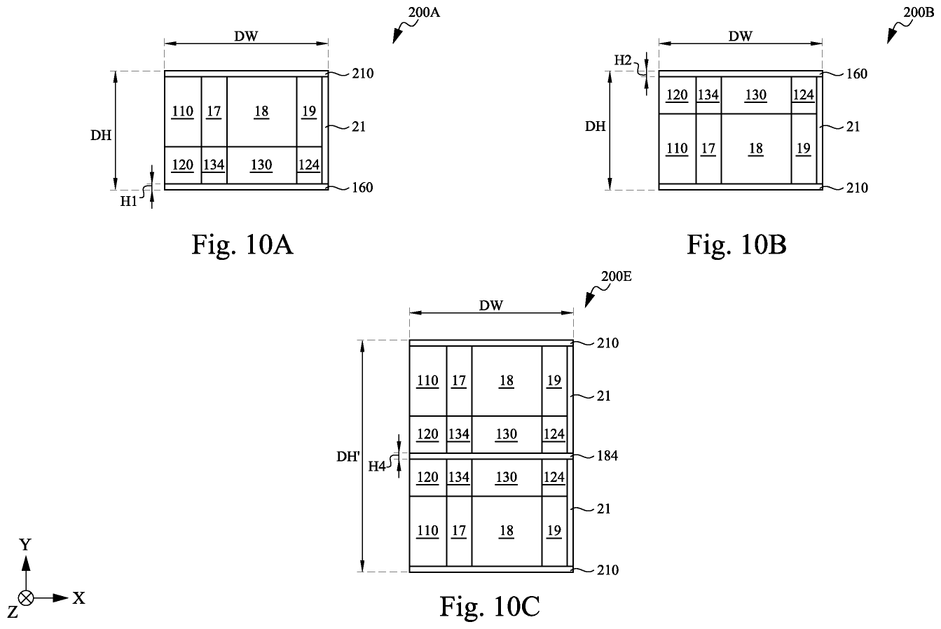

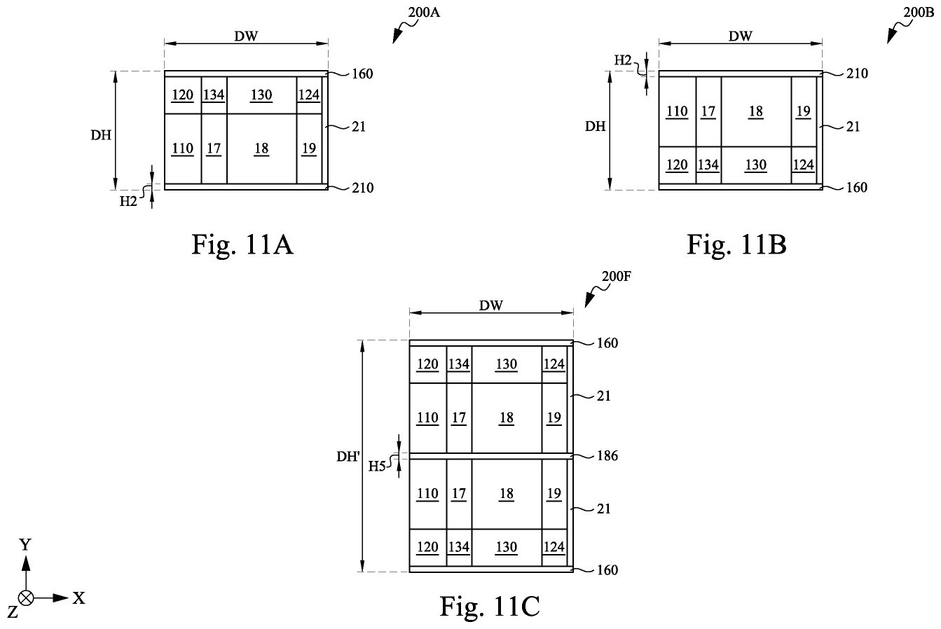

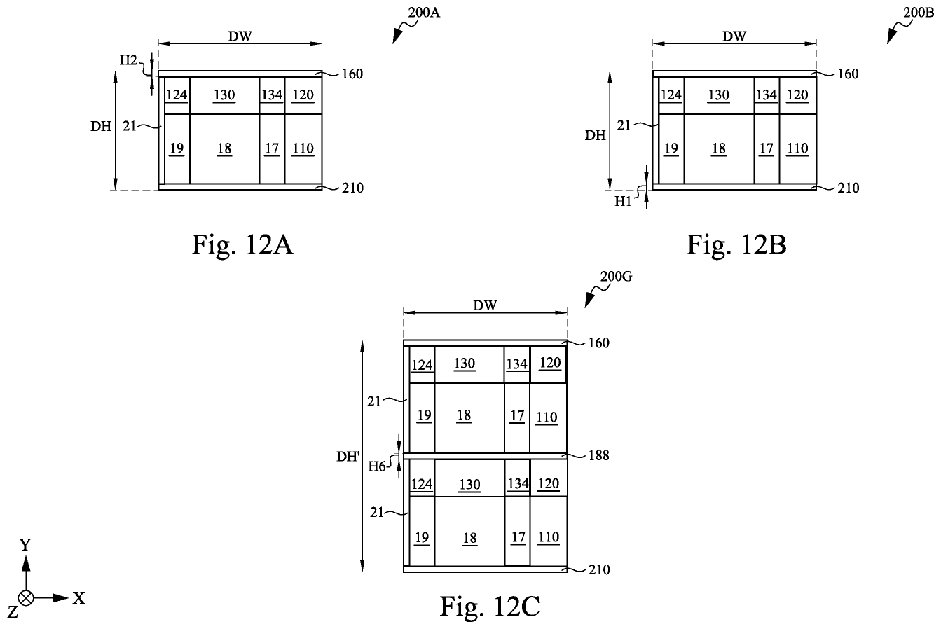

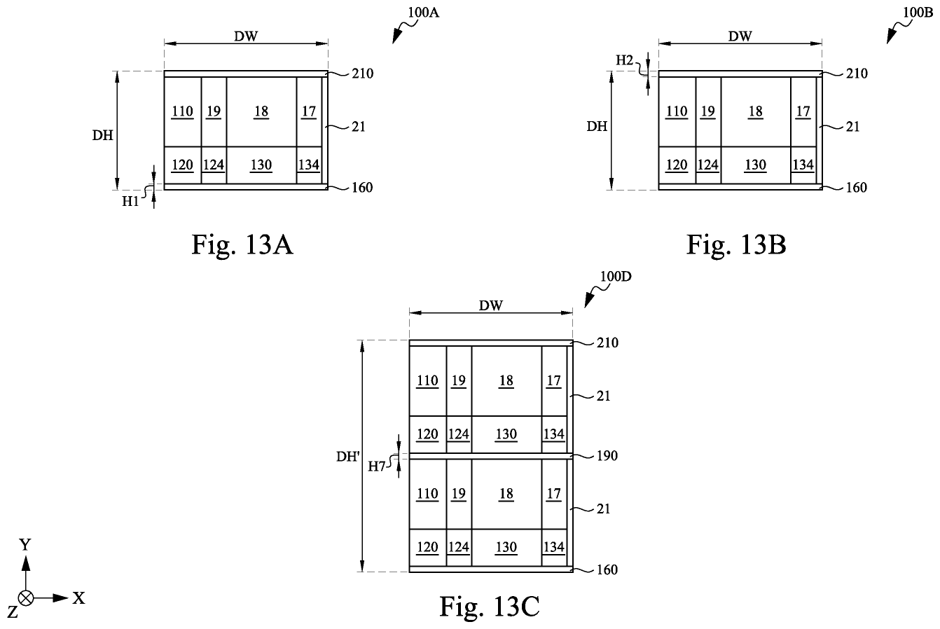

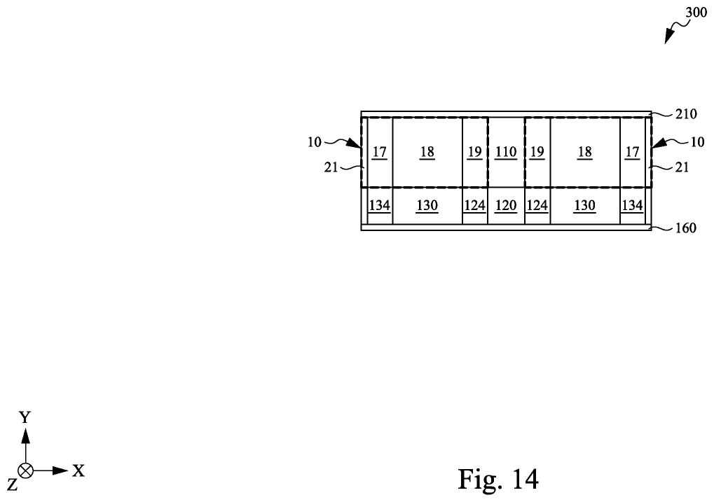

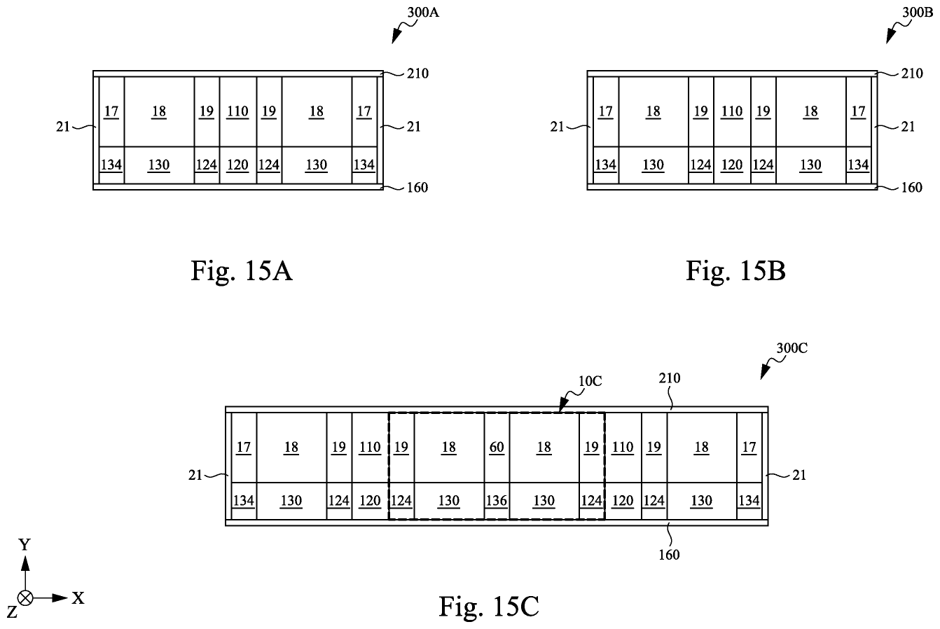

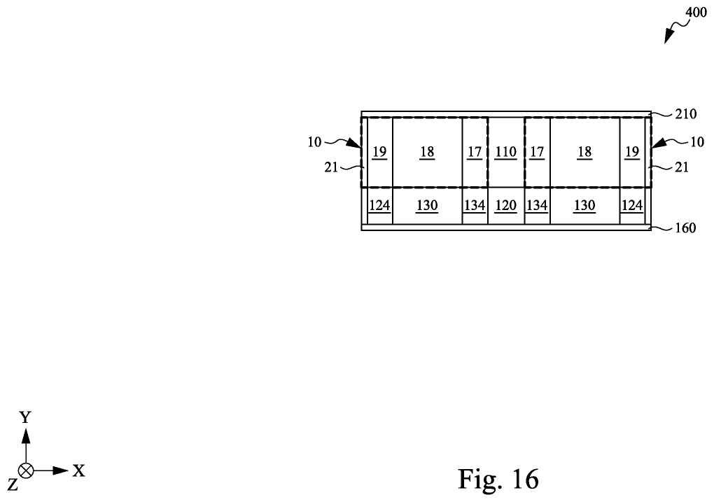

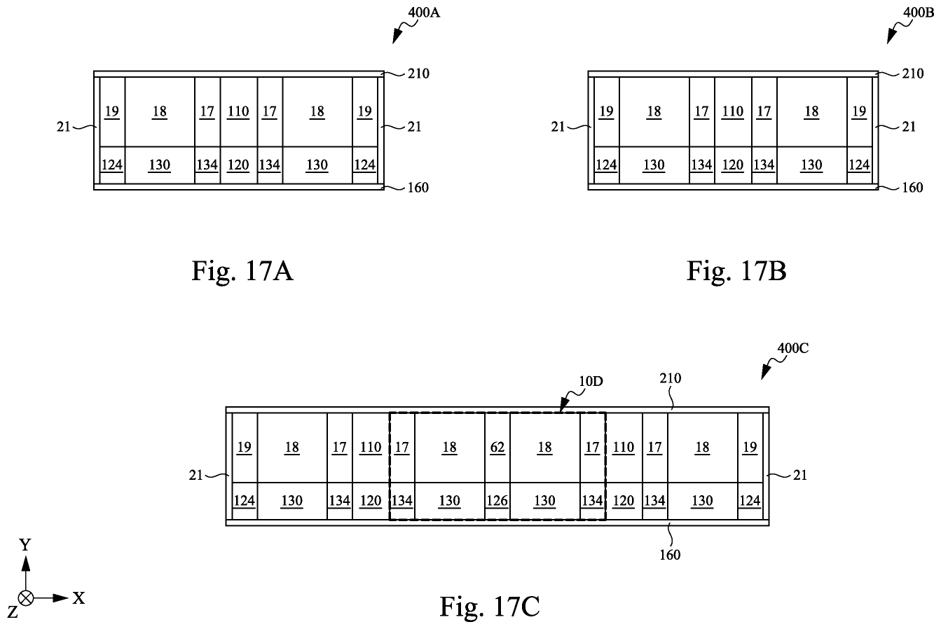

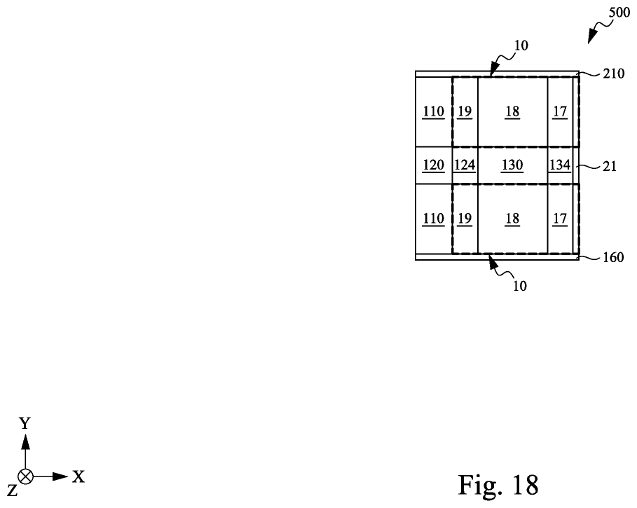

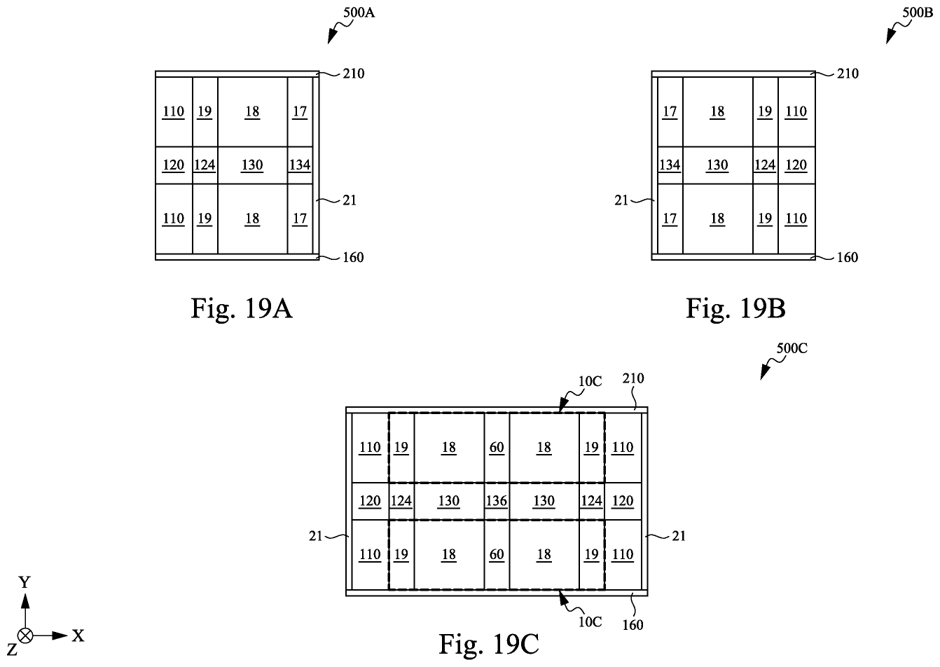

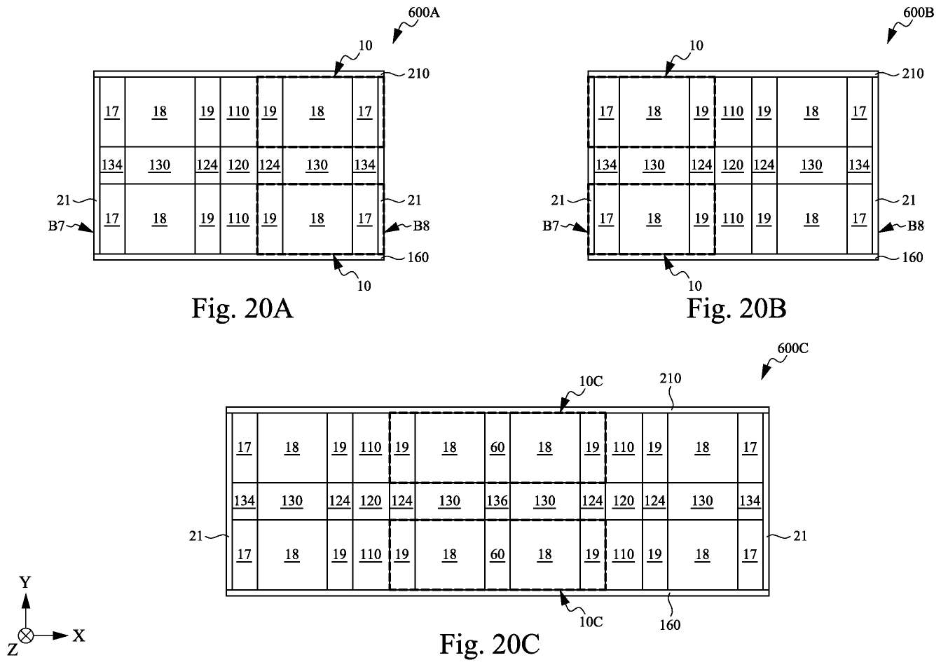

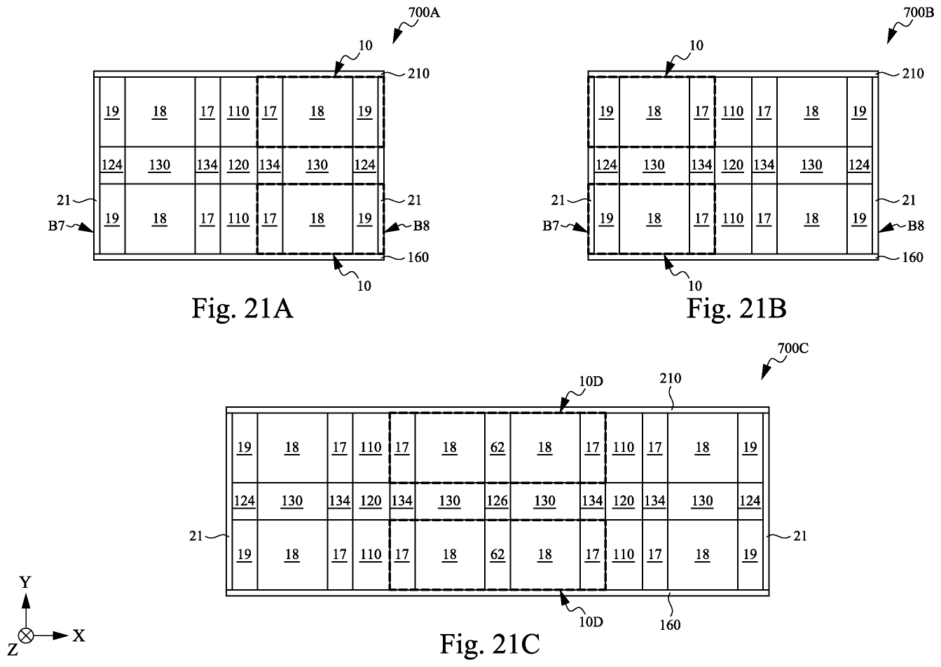

FIG. 5 illustrates an example schematic diagram of a semiconductor memory device 100 (hereafter referred to as a memory device 100), in accordance with various embodiments. The memory device (or macro) 100 includes an input/output (I/O) circuit 110, a control logic circuit 120, a word line driver 130, and the memory block 10 described herein, which includes at least the memory array 18. In the depicted embodiments, the I/O circuit 110 abuts a vertical boundary of the memory block 10 such that it is disposed adjacent to the memory block 10 along the first direction. In the present disclosure, the I/O circuit 110, the control logic circuit 120, and the word line driver 130 may be collectively referred to as the peripheral circuit of the memory device 100. Despite not being explicitly shown in FIG. 5, the various components of the memory device 100 may be electrically (or operatively) coupled to each other and to the control logic circuit 120. For example, the I/O circuit 110, the control logic circuit 120, and the word line driver 130 may be electrically coupled to the memory array 18. Although the components are shown in FIG. 5 as separate blocks for purposes of illustration, in some embodiments, some or all of the components may be integrated together.

The word line (WL) driver 130, which may include a row decoder and a word line voltage supply unit, can be responsible for activating word lines within the memory array 18. When data needs to be read from or written to a row of the memory cells 11 (see FIG. 1) of the memory array 18, the word line driver 130 may select the appropriate word line by driving it to a higher voltage level. The selected row of cells can then be read from or written to by sense amplifiers or write drivers connected to the bit lines, which run vertically and intersect with the word lines. The I/O circuit 110 is a hardware component that can access (e.g., read, program) each of memory cells asserted through an area decoder, such as the row decoder and a column decoder. The control logic circuit 120 is a hardware component that can control various coupled components of the memory device 100 (e.g., the components 18, 110, 120, and 130).

In some embodiments, referring to FIG. 5, the memory device 100 further includes a peripheral transition cell 124 and a peripheral transition cell 134, each of which is configured to accommodate the design and function of the peripheral logic circuit components, such as the control logic circuit 120 and/or the word line driver 130. In some embodiments, the peripheral transition cell 124 is aligned with the second strap cell 19 along the second direction, while the peripheral transition cell 134 is aligned with the first strap cell 17 along the second direction. As depicted herein, the edge cell 21 of the memory block 10 may extend along the second direction to abut the peripheral transition cell 134.

In some examples, the peripheral transition cell 124 may be configured as a strap cell that includes a well strap configured to be coupled to a power supply voltage in a manner similar to well strap disposed in the first strap cell 17. In a specific example, the peripheral transition cell 124 may include an n-type doped region, similar to the n-type doped region 14A, that includes an n-type well strap, similar to the n-type well strap 17A. Accordingly, the peripheral transition cell 124 electrically couples a portion of the substrate 12 (e.g., a portion of the substrate 12 providing PMOS devices) of the control logic circuit 120 to the first power supply voltage V_{DD}. Similarly, the peripheral transition cell 134 may be configured as a strap cell that includes a well strap configured to electrically couple a portion of the substrate 12 to a power supply voltage. Alternatively, one or both of the peripheral transition cells 124 and 134 may be configured as an edge cell similar to the edge cell 21 in both structure and function as described herein. In some embodiments, still referring to FIG. 5, the memory device 100 further includes a lower edge cell 160 and an upper edge cell 210 separated from the lower edge cell 160 along the second direction. Each of the lower edge cell 160 and the upper edge cell 210 traverses a width (e.g., width DW) of the memory device 100 along the first direction.

The memory device 100 has the width DW along the first direction and a height DH along the second direction, where the width DW and the height DH are greater than the width W and the height H, respectively, of the memory block 10 as defined herein. The structures and functions of the lower edge cell 160 and the upper edge cell 210 are similar to those of the edge cell 21 of the memory block 10. For example, a height Hl of the lower edge cell 160 and/or a height H2 of the upper edge cell 210 may be adjusted such that a ratio of the width DW to the height DH satisfies specific DRC constraints at a given technology node. In the present embodiments, the lower edge cell 160 has a height H1 and the upper edge cell 210 has a height H2. The present disclosure does not limit the height H1 and the height H2 to any specific values, so long as the ratio of the width DW to the height DH satisfies specific DRC constraints. For example, the height H1 may be the same as or different from the height H2.

Analogous to the embodiments depicted in FIGS. 3A-4D at the memory block level, embodiments depicted in FIGS. 6A-23C are directed to structures and arrangement of one or more transition cells at the memory device level to reduce the width DW and/or the height DH of the memory device 100.

In some embodiments, referring to FIGS. 6A-6C collectively, a first memory device 100A and a second memory device 100B, each of which is equivalent to the memory device 100 described herein, are adjoined (or coupled, merged, etc.) to one another by placing two (e.g., a first and a second) edge cells 21 in a side-by-side configuration along the first direction. In this regard, a vertical boundary of the first memory device 100A abuts that of the second memory device 100B, and the memory devices are arranged as mirror images of one another.

In the present embodiments, referring to FIG. 6C, adjoining the edge cell 21 of memory block 10 (e.g., 10A or 10B) of each of the memory devices 100A and 100B results in an adjoined memory device 100C that includes the adjoined memory block 10C as described herein. For example, adjoining the memory devices 100A and 100B at the edge cells 21 consolidates (or merges) the edge cells 21 and their respectively adjacent (e.g., a first and a second) first strap cells 17 to form the third strap cell 60 as depicted and described in the adjoined memory block 10C of FIGS. 3A-3E. In some embodiments, after merging the memory devices 100A and 100B, the peripheral circuit of each memory device remains in control of the operations of their respective memory blocks 10, i.e., each peripheral circuit is configured to control its corresponding memory array(s) 18.

Furthermore, adjoining the memory devices 100A and 100B at the edge cells 21 also consolidates the two peripheral transition cells 134 of the respective memory devices to form a peripheral transition cell 136. The resulting adjoined memory device 100C includes the third strap cell 60 and the peripheral transition cell 136 interposed between the two (e.g., a first and a second) memory arrays 18 of the respective memory devices, where the third strap cell 60 and the peripheral transition cell 136 are aligned along the second direction. In this regard, the third strap cell 60 and the peripheral transition cell 136 have the same width, such as the width W5 as defined in the adjoined memory block 10C. Still further, adjoining the memory devices 100A and 100B at the edge cells 21 merges the two (e.g., a first and a second) lower edge cells 160 and the two (e.g., a first and a second) upper edge cells 210.

In the present embodiments, the peripheral transition cell 136 serves substantially the same function as the peripheral transition cell 134. For example, if the peripheral transition cell 134 is configured as an edge cell, then the peripheral transition cell 136 is also configured as an edge cell. Alternatively, if the peripheral transition cell 134 is configured as a strap cell including a well strap as described in detail above, then the peripheral transition cell 136 is also configured to include the well strap. Notably, the width of the peripheral transition cell 136 corresponds to the width W5 of the third strap cell 60, which has been described in detail above with respect to the adjoined memory block 10C.

Furthermore, analogous to the description of the reduction in the width of the adjoined memory block 10C, merging the memory devices 100A and device 100B reduces the overall width W′ of the memory blocks in the adjoined memory device 100C due to the width W5 of the third strap cell 60 being less than the sum of the widths W2 (i.e., less than 2*W2) of the two adjoined first strap cells 17 (with the two edge cells 21 removed). This, in turn, reduces the overall dimension DW' of the adjoined memory device 100C to be less than 2*DW, where the width DW accounts for the width W of the memory block 10 in each of the memory devices 100A and 100B.

FIG. 7 depicts a memory device 200 similar to the memory device 100 of FIG. 5. For example, the memory device 200 includes the I/O circuit 110, the control logic circuit 120, the word line driver 130, and the memory block 10. The memory device 200 further includes the peripheral transition cells 124 and 134 each disposed adjacent to the control logic circuit 120 and the word line driver 130, respectively. The memory device 200 further includes the lower edge cell 160 and the upper edge cell 210 each traversing the width DW of the memory device 200, which also is defined by the height DH along the second direction. Different from the memory device 100, the I/O circuit 110 of the memory device 200 abuts a vertical boundary of the memory block 10 at the first strap cell 17, while the I/O circuit 110 of the memory device 100 abuts a vertical boundary of the memory block 10 at the second strap cell 19. Descriptions of the features that are common to both the memory device 100 and 200 are omitted herein for purposes of brevity.

Referring to FIGS. 8A-8C collectively, a first memory device 200A and a second memory device 200B, each of which is equivalent to the memory device 200 described herein, are adjoined (or coupled, merged, etc.) to one another by placing two (e.g., a first and a second) second strap cell 19 in a side-by-side configuration along the first direction, such that the vertical boundary of the first memory device 200A abuts that of the second memory device 200B, and the memory devices are presented as mirror images of one another. In some embodiments, after merging the memory devices 200A and 200B, the peripheral circuit of each memory device remains in control of the operations of their respective memory blocks 10, i.e., each peripheral circuit is configured to control its corresponding memory array(s) 18.

In the present embodiments, referring to FIG. 8C, adjoining the second strap cell 19 of memory block 10 of each of the memory devices 200A and 200B results in an adjoined memory device 200C that includes the adjoined memory block 10D as described herein. For example, adjoining the memory devices 200A and 200B at the second strap cell 19 consolidates the second strap cells 19 to form the fourth strap cell 62 as depicted and described in the adjoined memory block 10D of FIGS. 4A-4D.

Adjoining the memory devices 200A and 200B at the second strap cell 19 also consolidates the two peripheral transition cells 124 of the respective memory devices to form a peripheral transition cell 126. The resulting adjoined memory device 200C includes the fourth strap cell 62 and the peripheral transition cell 126 interposed between the two (e.g., a first and a second) memory arrays 18 of the respective memory devices, where the fourth strap cell 62 and the peripheral transition cell 126 are aligned along the second direction. In this regard, the third strap cell 60 and the peripheral transition cell 126 have the same width, such as the width W6 as defined in the adjoined memory block 10D. Similar to the relationship between the peripheral transition cell 134 and the peripheral transition cell 136, the peripheral transition cell 126 serves substantially the same function as the peripheral transition cell 124. Still further, adjoining the memory devices 200A and 200B at the second strap cell 19 merges the two (e.g., a first and a second) lower edge cells 160 and the two (e.g., a first and a second) upper edge cells 210 in a manner similar to that of adjoining the memory devices 200A and 200B.

Analogous to the description of the reduction in the width of the adjoined memory block 10D, merging the memory devices 200A and 200B reduces the overall width W″ of the memory blocks in the adjoined memory device 100C due to the width W6 of the fourth strap cell 62 being less than the sum of the widths W3 (i.e., less than 2*W3) of the two adjoined second strap cells 19. This, in turn, reduces the overall dimension DW' of the adjoined memory device 200C to be less than 2*DW, where the width DW accounts for the width W of the memory block 10 in each of the memory devices 200A and 200B.

In some embodiments, referring to FIGS. 9A-9C collectively, the memory devices 200A and 200B are adjoined to one another by placing the lower edge cell 160 of the memory device 200A and the upper edge cell 210 of the memory device 200B in a top-to-bottom configuration along the second direction, such that a horizontal boundary of the first memory device 200A abuts that of the second memory device 200B. In the present embodiments, referring to FIG. 9C, adjoining the memory devices 200A and 200B in this configuration results in an adjoined memory device 200D that includes a single middle edge cell 182 interposed between two vertically stacked memory blocks 10 of the memory devices 200A and 200B. In the depicted embodiments, the middle edge cell 182 abuts one of the memory arrays 18, such as the memory array 18 in the lower memory block 10 (i.e., the memory device 200B), which is between the middle edge cell 182 and the lower edge cell 160. In some embodiments, after merging the memory devices 200A and 200B along the second direction, the peripheral circuit of each memory device remains in control of the operations of their respective memory blocks 10, i.e., each peripheral circuit is configured to control its corresponding memory arrays(s) 18.

In a manner similar to the consolidation of two first strap cells 17 or two second strap cells 19, the consolidated middle edge cell 182 has a height H3 that is less than a sum of the height H1 of the lower edge cell 160 and the height H2 of the upper edge cell 210. As such, the overall height DH′ of the adjoined memory device 200D is less than a sum of the height DH (i.e., less than 2*DH) of each of the memory devices 200A and 200B. The present disclosure does not limit the height H3 to any specific value within this range, so long as the ratio of the width DW to the height DH′ satisfies the specific DRC constraints.

In some embodiments, referring to FIGS. 10A-10C collectively, the memory devices 200A and 200B are adjoined to one another by placing the lower edge cell 160 of the memory device 200A and the lower edge cell 160 of the memory device 200B in a top-to-bottom configuration along the second direction, such that a horizontal boundary of the first memory device 200A abuts that of the second memory device 200B. In the present embodiments, referring to FIG. 10C, adjoining the memory devices 200A and 200B in this configuration results in an adjoined memory device 200E that includes a single middle edge cell 184 interposed between two vertically stacked memory blocks 10 of the memory devices 200A and 200B. The two memory devices 200A and 200B are thus arranged as mirror images about the middle edge cell 184. In the depicted embodiments, the middle edge cell 184 abuts the peripheral circuits (e.g., the control logic circuit 120 and the word line driver 130, etc.) of the memory devices 200A and 200B but is separated from each of the memory arrays 18 along the second direction.

Similar to the consolidated middle edge cell 182, the consolidated middle edge cell 184 has a height H4 that is less than a sum of the height Hl of each of the lower edge cells 160 (i.e., less than 2*H1). The overall height DH′ of the adjoined memory device 200E is similarly less than the sum of the height DH (i.e., less than 2*DH) of each of the memory devices 200A and 200B. The present disclosure does not limit the height H4 to any specific value within this range, so long as the ratio of the width DW to the height DH′ satisfies the specific DRC constraints.

In some embodiments, referring to FIGS. 11A-11C collectively, the memory devices 200A and 200B are adjoined to one another by placing the upper edge cell 210 of the memory device 200A and the upper edge cell 210 of the memory device 200B in a top-to-bottom configuration along the second direction, such that a horizontal boundary of the first memory device 200A abuts that of the second memory device 200B. In the present embodiments, referring to FIG. 11C, adjoining the memory devices 200A and 200B in this configuration results in an adjoined memory device 200F that includes a single middle edge cell 186 interposed between two vertically stacked memory blocks 10 of the memory devices 200A and 200B. The two memory devices 200A and 200B are thus arranged as mirror images about the middle edge cell 186. In the depicted embodiments, the middle edge cell 186 abuts each memory array 18 of the upper and the lower memory blocks 10 (i.e., the memory devices 200A and 200B).

The consolidated middle edge cell 186 has a height H5 that is less than a sum of the height H2 of each of the upper edge cells 210 (i.e., less than 2*H2). The overall height DH′ of the adjoined memory device 200F is similarly less than the sum of the height DH (i.e., less than 2*DH) of each of the memory devices 200A and 200B. The present disclosure does not limit the height H5 to any specific value within this range, so long as the ratio of the width DW to the height DH′ satisfies the specific DRC constraints.

In some embodiments, referring to FIGS. 12A-12C collectively, the memory devices 200A and 200B are adjoined to one another by placing the upper edge cell 210 of the memory device 200A and the lower edge cell 160 of the memory device 200B in a top-to-bottom configuration along the second direction, such that a horizontal boundary of the first memory device 200A abuts that of the second memory device 200B. In the present embodiments, referring to FIG. 12C, adjoining the memory devices 200A and 200B in this configuration results in an adjoined memory device 200G that includes a single middle edge cell 188 interposed between two vertically stacked memory blocks 10 of the memory devices 200A and 200B. In the depicted embodiments, the middle edge cell 188 abuts one of the memory arrays 18, such as the memory array 18 in the upper memory block 10 (i.e., the memory device 200A), which is between the middle edge cell 188 and the lower edge cell 160.

The consolidated middle edge cell 188 has a height H6 that is less than a sum of the height H1 of the lower edge cell 160 and the height H2 of the upper edge cell 210. The overall height DH′ of the adjoined memory device 200G is similarly less than the sum of the height DH (i.e., less than 2*DH) of each of the memory devices 200A and 200B. The present disclosure does not limit the height H6 to any specific value within this range, so long as the ratio of the width DW to the height DH′ satisfies the specific DRC constraints.

Various arrangements of the memory devices 200A and 200B depicted in FIGS. 9A-12C may also be applicable to the memory devices 100A and 100B. For example, referring to FIGS. 13A-13C collectively, the memory devices 100A and 100B are adjoined to one another by placing the lower edge cell 160 of the memory device 100A and the upper edge cell 210 of the memory device 100B in a top-to-bottom configuration along the second direction, such that a horizontal boundary of the first memory device 100A abuts that of the second memory device 100B. In the present embodiments, referring to FIG. 13C, adjoining the memory devices 100A and 100B in this configuration results in an adjoined memory device 100D that includes a single middle edge cell 190 interposed between two vertically stacked memory blocks 10 of the memory devices 100A and 100B. The consolidated middle edge cell 190 has a height H7 that is less than a sum of the height H1 of the lower edge cell 160 and the height H2 of the upper edge cell 210. As such, the overall height DH′ of the adjoined memory device 100D is less than a sum of the height DH (i.e., less than 2*DH) of each of the memory devices 200A and 200B.

In some embodiments, as depicted in FIGS. 5-13C, the I/O circuit 110 of each of the memory devices 100 (e.g., 100A and 100B) and 200 (e.g., 200A and 200B) abuts the vertical boundary (e.g., along the second direction) of the memory block 10, where the I/O circuit 110 provides one-sided control for the memory array 18. In other words, each peripheral circuit is configured to control one memory block 10 (or one bank containing a single memory block 10) In some embodiments, as depicted in FIGS. 14-17C, analogous memory devices 300 and 400 each include the I/O circuit 110 (and the control logic circuit 120) that is interposed between two memory blocks 10 (or two banks of memory blocks 10 with each bank containing one memory block 10), such that the two memory arrays 18 are symmetrically disposed about and operationally controlled by the I/O circuit 110 along the first direction.

For example, referring to FIG. 14, the memory device 300 has a structure similar to the memory devices 100 and 200 with the exception that the I/O circuit 110 of the memory device 300 is flanked by two memory blocks 10 along the first direction, where the I/O circuit 110 abuts the second strap cell 19 of each of the memory blocks 10 and the first strap cells 17 are disposed along outer boundary of the memory device 300. In this regard, the I/O circuit 110 of the memory device 300 provides control to the two symmetrically arranged memory blocks 10 along the first direction.

In some embodiments, various arrangements of the memory device 100 are also applicable to the memory device 300. For example, referring to FIGS. 15A-15C, a first memory device 300A and a second memory device 300B, each of which is equivalent to the memory device 300 described herein, are adjoined to one another by placing two (e.g., a first and a second) edge cells 21 in a side-by-side configuration along the first direction to form an adjoined memory device 300C.

Similar to the adjoined memory device 100C, referring to FIG. 15C, the adjoined memory device 300C includes the adjoined memory block 10C that consolidates the edge cells 21 and their respectively adjacent (e.g., a first and a second) first strap cells 17 to form the third strap cell 60. In this regard, the memory devices 300A and 300B are arranged as mirror images of one another about the third strap cell 60. Furthermore, adjoining the memory devices 300A and 300B at the edge cells 21 also forms the peripheral transition cell 136. In this regard, the third strap cell 60 and the peripheral transition cell 136 have the same width, such as the width W5 as defined in the adjoined memory block 10C.

In some embodiments, referring to FIG. 16, the memory device 400 has a structure similar to the memory device 300 with the exception that the I/O circuit 110 abuts the first strap cell 17 of each of the memory blocks 10 and the second strap cells 19 are disposed along outer boundary of the memory device 400.

In some embodiments, various arrangements of the memory device 200 are also applicable to the memory device 400. For example, referring to FIGS. 17A-17C, a first memory device 400A and a second memory device 400B, each of which is equivalent to the memory device 300 described herein, are adjoined to one another by placing two (e.g., a first and a second) second strap cells 19 in a side-by-side configuration along the first direction to form an adjoined memory device 400C. Similar to the adjoined memory device 200C, referring to FIG. 17C, the adjoined memory device 400C includes the adjoined memory block 10D that consolidates the second strap cells 19 to form the fourth strap cell 62. In this regard, the memory devices 400A and 400B are arranged as mirror images of one another about the fourth strap cell 62. Furthermore, adjoining the memory devices 400A and 400B at the second strap cell 19 also forms the peripheral transition cell 126, which as the same width, such as the width W6, as the fourth strap cell 62.

In some embodiments, as depicted in FIGS. 18-19C, analogous memory device 500 includes two I/O circuits 110 each abutting a common control logic circuit 120 along the second direction and abutting the vertical boundary of each memory block 10 along the first direction, where two of such memory blocks 10 are stacked along the second direction and separated by the word line driver 130 and the peripheral transition cells 124 and 134. The I/O circuits 110 are each configured to control the adjacent memory block 10. The memory device 500 further includes the lower edge cell 160 abutting a boundary of the lower memory block 10 and the upper edge cell 210 abutting a boundary of the upper memory block 10.

In some embodiments, various arrangements of the memory device 100 are also applicable to the memory device 500. For example, referring to FIGS. 19A-19C, a first memory device 500A and a second memory device 500B, each of which is equivalent to the memory device 500 described herein, are adjoined to one another by placing two (e.g., a first and a second) edge cells 21 in a side-by-side configuration along the first direction to form an adjoined memory device 500C. Similar to the adjoined memory device 100C, referring to FIG. 19C, the adjoined memory device 500C includes the adjoined memory block 10C from each pair of the upper and lower memory blocks 10, where each adjoined memory block 10C consolidates the adjacent edge cells 21 and their respectively adjacent (e.g., a first and a second) first strap cells 17 to form the third strap cell 60. The adjacent peripheral transition cells 134 are also consolidated to form the peripheral transition cell 136 such that the adjoined memory blocks 10C in the upper portion and the lower portion of the memory device 500C are separated by the peripheral transition cell 136. In this regard, the memory devices 500A and 500B are arranged as mirror images of one another about the third strap cell 60. Furthermore, adjoining the memory devices 500A and 500B at the edge cells 21 also forms the peripheral transition cell 136, which as the same width, such as the width W5, as the third strap cell 60.

In some embodiments, as depicted in FIGS. 5-19C, the I/O circuit 110 of each of the memory devices 100 (e.g., 100A and 100B), 200 (e.g., 200A and 200B), 300 (e.g., 300A and 300B), 400 (e.g., 400A and 400B), and 500 (e.g., 500A and 500B) operationally controls a single bank containing one memory array 18 from one memory block 10. In some embodiments, as depicted in FIGS. 20A-23C, analogous memory devices 600A, 600B, 700A, 700B, 800A, 800B, 900A, and 900B each include the I/O circuit 110 (and the control logic circuit 120) that is configured to control the operations of more than one banks of memory arrays 18, where each bank includes more than one memory arrays 18 from their respective memory blocks 10, such as two memory blocks 10 stacked along the second direction.

In some embodiments, referring to FIGS. 20A-21C, the memory device includes an even number of banks flanking the I/O circuit 110. For example, each of the memory devices 600A, 600B, 700A, and 700B includes one bank on each side of the I/O circuit 110, and each bank includes two memory arrays 18 (i.e., two memory blocks 10) stacked along the second direction. In some embodiments, referring to FIGS. 22A-23C, the memory device includes an uneven number of banks flanking the I/O circuit 110. For example, each of the memory devices 800A, 800B, 900A, and 900B includes one bank on one side of the I/O circuit 110 proximal to a vertical boundary B7 and two banks on the opposite side of the I/O circuit 110 proximal to a vertical boundary B8, and each bank includes two memory arrays 18 (i.e., two memory blocks 10) stacked along the second direction.

In some embodiments, referring to FIGS. 20A-20C, the memory devices 600A and 600B are adjoined at two (e.g., a first and a second) edge cells 21 in the side-by-side configuration along the first direction, thereby consolidating the edge cells 21 and their respectively adjacent first strap cells 17 to form the third strap cell 60 (see FIG. 20C). The adjacent peripheral transition cells 134 are also consolidated to form the peripheral transition cell 136 such that the adjoined memory blocks 10C in the upper portion and the lower portion of the memory device 600C are separated by the peripheral transition cell 136. In some embodiments, after merging the memory devices 600A and 600B along the first direction, the peripheral circuit of each memory device remains in control of the operations of their respective memory blocks 10, i.e., each peripheral circuit is configured to control its corresponding banks of the memory arrays 18. Similar arrangement is implemented for the memory devices 800A, 800B, and 800C, as depicted in FIGS. 22A-22C.

In some embodiments, referring to FIGS. 21A-21C, the memory devices 700A and 700B are adjoined at two (e.g., a first and a second) second strap cells 19 in the side-by-side configuration along the first direction, thereby consolidating the second strap cells 19 to form the fourth strap cell 62 (see FIG. 21C). The adjacent peripheral transition cells 124 are also consolidated to form the peripheral transition cell 126 in a manner similar to that depicted in FIG. 17C. Similar arrangement is implemented for the memory devices 900A, 900B, and 900C, as depicted in FIGS. 23A-23C.

In some embodiments, the various memory devices provided herein each include mergeable strap cells disposed along both the vertical outer boundaries B7 and B8 of the memory device, which are separated along the first direction. The mergeable strap cells, i.e., the first strap cell 17 and the second strap cell 19, may be of the same type, such as those depicted in the memory devices 600A/B, 700A/B, and 800A/B. Alternatively, the mergeable strap cells may be of different types, such as those depicted in the memory devices 900A/B. Different placements of the mergeable strap cells allow different consolidated (or center) strap cells, i.e., the third strap cell 60 and the fourth strap cell 62, to be formed in the memory devices, providing greater design flexibility with improved scalability.

FIG. 24 illustrates a schematic representation of the memory component of an example memory device 1000, according to some embodiments of the present disclosure. For purposes of simplicity, the peripheral circuit components (e.g., I/O circuit, control logic circuit, word line driver, etc.) of the memory device 1000 are omitted in FIG. 24. The memory component includes a plurality of memory blocks 1001 each analogous to (i.e., having similar or substantially the same structure) the memory block 10 and arranged in a grid having M columns and N rows, where M and N are both greater than or equal to one. The memory device 1000 includes an upper edge cell 1020 and a lower edge cell 1010, which are analogous to the upper edge cell 210 and the lower edge cell 160, respectively. Two adjacent memory blocks 1001 along the first direction are separated by a consolidated strap cell 1050, which is analogous to the third strap cell 60 or the fourth strap cell 62. In addition, two adjacent memory blocks 1001 along the second direction are separated by a middle edge cell 1030, which is analogous to any of the middle edge cells 182-188. In the present embodiments, one or more of the consolidated strap cells 1050 and the middle edge cells 1030 are configured to reduce a width GDH′ and a height GDW′, respectively, of the memory device 1000, achieving higher chip density in the memory devices (e.g., SRAM devices).

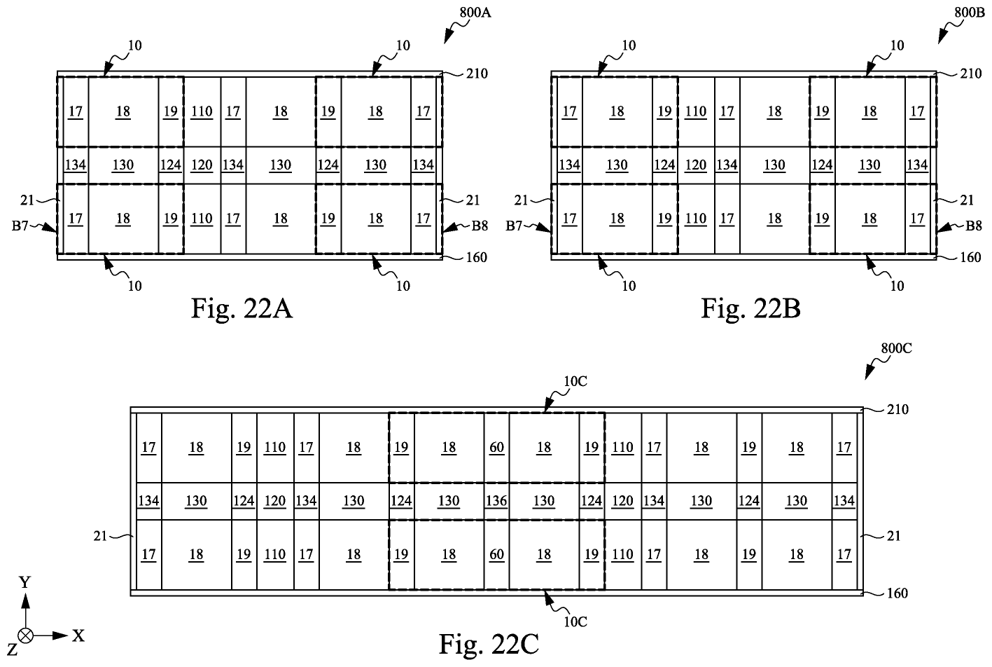

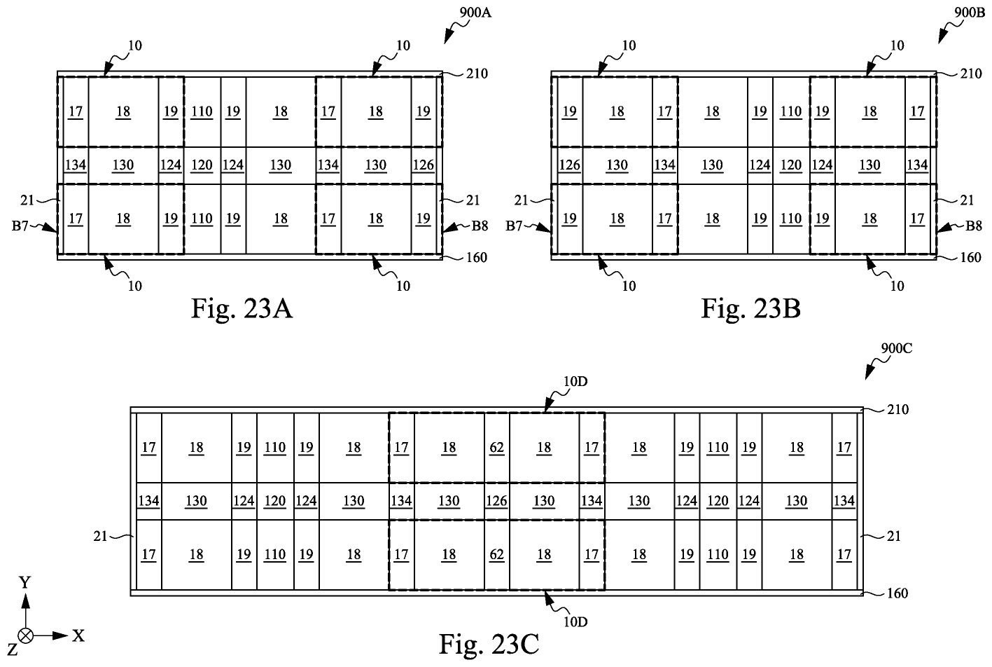

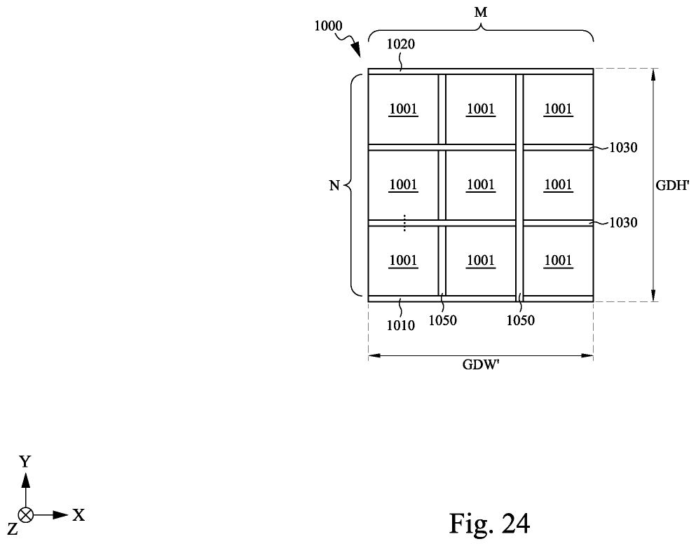

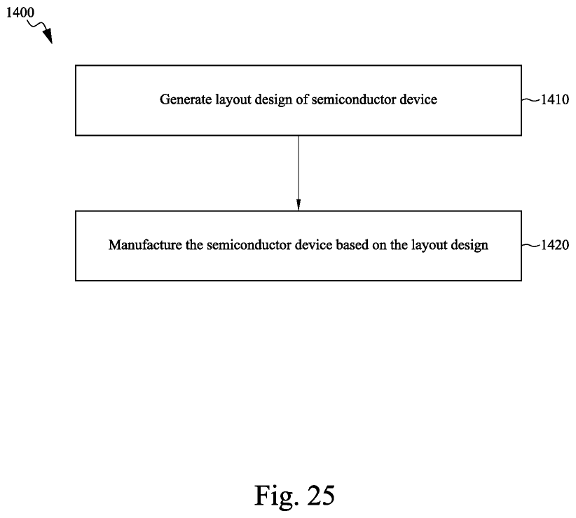

FIG. 25 is a flowchart of a method 1400 of forming or manufacturing a semiconductor device, such as any of the memory block 10 or any of the memory devices 100-1000, in accordance with some embodiments. It is understood that additional operations may be performed before, during, and/or after the method 1400 depicted in FIG. 25.

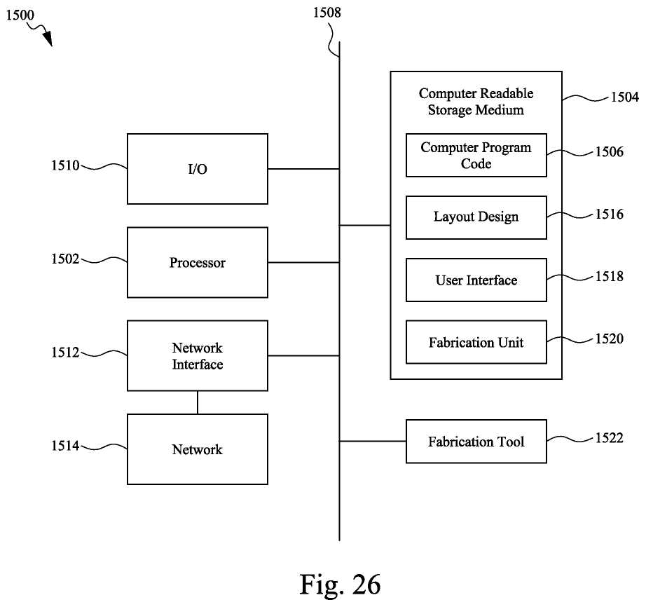

In operation 1410 of the method 1400, a layout design of a semiconductor device is generated. The operation 1410 is performed by a processing device (e.g., processor 1502 of FIG. 26) configured to execute instructions for generating a layout design. In one approach, the layout design is generated by placing layout designs of one or more standard cells through a user interface. In one approach, the layout design is automatically generated by a processor executing a synthesis tool that converts a logic design (e.g., Verilog) into a corresponding layout design. In some embodiments, the layout design is rendered in a graphic database system (GDSII) file format. In some embodiments, the layout design includes one that is similar to the example layout depicted in FIG. 2, which is an embodiment of the memory block 10 described herein.

In operation 1420 of the method 1400, a semiconductor device is manufactured based on the layout design. In some embodiments, the operation 1420 of the method 1400 includes manufacturing at least one mask based on the layout design, and manufacturing a semiconductor device based on the at least one mask. Example manufacturing operations of the operation 1420 may include patterning, implantation, deposition, etching, planarization, the like, or combinations thereof, to form a plurality of front-end-of-line device features (e.g., the n-type doped region 14, the p-type doped region 16, the n-type well strap 17A, the p-type well strap 17B, the fins 20-26, the epitaxial source/drain features 40A-40D, the gate structures 30A-30C, etc.), device-level contacts, and interconnect features including vias (e.g., the vias 50-56) and conductive lines.

In some embodiments, the method 1400 is implemented as a standalone software application for execution by a processor. In some embodiments, the method 1400 is implemented as a software application that is a part of an additional software application. In some embodiments, the method 1400 is implemented as a plug-in to a software application. In some embodiments, the method 1400 is implemented as a software application that is a portion of an EDA tool. In some embodiments, the method 1400 is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated based on a netlist which is created based on the schematic design.

FIG. 26 is a schematic view of a system 1500 for designing and manufacturing an IC layout design, in accordance with some embodiments. The system 1500 generates or places one or more IC layout designs, as described herein. In some embodiments, the system 1500 manufactures one or more semiconductor devices based on the one or more IC layout designs, as described herein. The system 1500 includes a (e.g., hardware) processor 1502 and a non-transitory, computer readable storage medium 1504 encoded with, e.g., storing, computer program code 1506, e.g., a set of executable instructions. The computer readable storage medium 1504 is configured to interface with manufacturing machines for producing the semiconductor device. The processor 1502 is electrically coupled to the computer readable storage medium 1504 by a bus 1508. The processor 1502 is also electrically coupled to an I/O interface 1510 by the bus 1508. A network interface 1512 is also electrically connected to the processor 1502 by the bus 1508. Network interface 1512 is connected to a network 1514, so that the processor 1502 and the computer readable storage medium 1504 can connect to external elements via network 1514. The processor 1502 is configured to execute the computer program code 1506 encoded in the computer readable storage medium 1504 to cause the system 1500 to be usable for performing a portion or all of the operations as described in method 1400.

In some embodiments, the processor 1502 is a central processing unit (CPU), a multi-processor, a distributed processing system, an application specific integrated circuit (ASIC), and/or a suitable processing unit.

In some embodiments, the computer readable storage medium 1504 is an electronic, magnetic, optical, electromagnetic, infrared, and/or a semiconductor system (or apparatus or device). For example, the computer readable storage medium 1504 includes a semiconductor or solid-state memory, a magnetic tape, a removable computer diskette, a random-access memory (RAM), a read-only memory (ROM), a rigid magnetic disk, and/or an optical disk. In some embodiments using optical disks, the computer readable storage medium 1504 includes a compact disk-read only memory (CD-ROM), a compact disk-read/write (CD-R/W), and/or a digital video disc (DVD).

In some embodiments, the computer readable storage medium 1504 stores the computer program code 1506 configured to cause the system 1500 to perform the method 1400. In some embodiments, the computer readable storage medium 1504 also stores information needed for performing the method 1400 as well as information generated during the performance of the method 1400, such as layout design 1516, user interface 1518, fabrication unit 1520, and/or a set of executable instructions to perform the operation of method 1400.

In some embodiments, the computer readable storage medium 1504 stores instructions (e.g., the computer program code 1506) for interfacing with manufacturing machines. The instructions (e.g., the computer program code 1506) enable the processor 1502 to generate manufacturing instructions readable by the manufacturing machines to effectively implement the method 1400 during a manufacturing process.

The system 1500 includes the I/O interface 1510. The I/O interface 5110 is coupled to external circuitry. In some embodiments, the I/O interface 1510 includes a keyboard, keypad, mouse, trackball, trackpad, and/or cursor direction keys for communicating information and commands to the processor 1502.

The system 1500 also includes the network interface 1512 coupled to the processor 1502. The network interface 1512 allows the system 1500 to communicate with the network 1514, to which one or more other computer systems are connected. The network interface 1512 includes wireless network interfaces such as BLUETOOTH, WIFI, WIMAX, GPRS, or WCDMA; or wired network interface such as ETHERNET, USB, or IEEE-13154. In some embodiments, the method 1400 is implemented in two or more systems 1500, and information such as layout design, user interface and fabrication unit are exchanged between different systems 1500 by the network 1514.

The system 1500 is configured to receive information related to a layout design through the I/O interface 1510 or network interface 1512. The information is transferred to the processor 1502 by the bus 1508 to determine a layout design for producing an IC. The layout design is then stored in the computer readable storage medium 1504 as the layout design 1516. The system 1500 is configured to receive information related to a user interface through the I/O interface 1510 or network interface 1512. The information is stored in the computer readable storage medium 1504 as the user interface 1518. The system 1500 is configured to receive information related to a fabrication unit through the I/O interface 1510 or network interface 1512. The information is stored in the computer readable storage medium 1504 as the fabrication unit 1520. In some embodiments, the fabrication unit 1520 includes fabrication information utilized by the system 1500.

In some embodiments, the method 1400 is implemented by a manufacturing device to manufacture an integrated circuit using a set of masks manufactured based on one or more layout designs generated by the system 1500. In some embodiments, the system 1500 includes a manufacturing device (e.g., fabrication tool 1522) to manufacture an integrated circuit using a set of masks manufactured based on one or more layout designs of the present disclosure. In some embodiments, the system 1500 of FIG. 26 generates layout designs of an IC that are smaller than other approaches. In some embodiments, the system 1500 of FIG. 26 generates layout designs of a semiconductor device that occupy less area than other approaches.

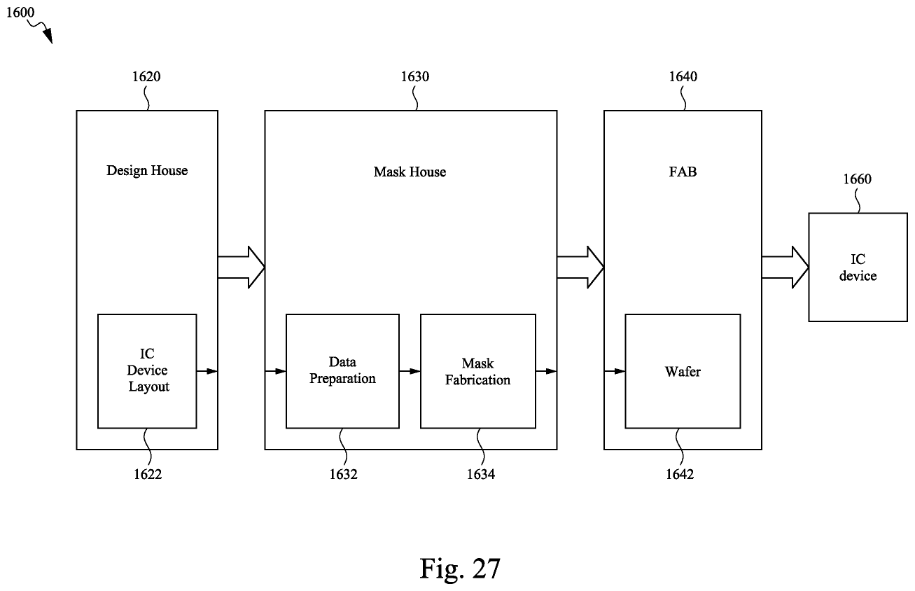

FIG. 27 is a block diagram of an integrated circuit (IC)/semiconductor device manufacturing system 1600, and an IC manufacturing flow associated therewith, in accordance with at least one embodiment of the present disclosure.

In FIG. 27, the IC manufacturing system 1600 includes entities, such as a design house 1620, a mask house 1630, and an IC manufacturer/fabricator (“fab”) 1640, that interact with one another in the design, development, and manufacturing cycles and/or services related to manufacturing an IC device (semiconductor device) 1660 (e.g., corresponding to the memory block 10 or the memory devices 100-1000). The entities in the IC manufacturing system 1600 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1620, mask house 1630, and IC fab 1640 is owned by a single company. In some embodiments, two or more of design house 1620, mask house 1630, and IC fab 1640 coexist in a common facility and use common resources.

The design house (or design team) 1620 generates an IC design layout 1622. The IC design layout 1622 includes various geometrical patterns designed for the IC device 1660. The geometrical patterns correspond to patterns of metal, oxide, or semiconductor layers that make up the various components of the IC device 1660 to be fabricated. The various layers combine to form various IC features. For example, a portion of the IC design layout 1622 includes various IC features, such as an active region, gate structures, source/drain regions, interconnect structures, and openings for bonding pads, to be formed in a semiconductor substrate (such as a silicon wafer) and various material layers disposed on the semiconductor substrate. The design house 1620 implements a proper design procedure to form the IC design layout 1622. The design procedure includes one or more of logic design, physical design or place and route. The IC design layout 1622 is presented in one or more data files having information of the geometrical patterns. For example, the IC design layout 1622 can be expressed in a GDSII file format or DFII file format.

The mask house 1630 includes mask data preparation 1632 and mask fabrication 1634. The mask house 1630 uses the IC design layout 1622 to manufacture one or more masks to be used for fabricating the various layers of the IC device 1660 according to the IC design layout 1622. The mask house 1630 performs the mask data preparation 1632, where the IC design layout 1622 is translated into a representative data file (“RDF”). The mask data preparation 1632 provides the RDF to the mask fabrication 1634. The mask fabrication 1634 includes a mask writer. A mask writer converts the RDF to an image on a substrate, such as a mask (reticle) or a semiconductor wafer. The design layout is manipulated by the mask data preparation 1632 to comply with particular characteristics of the mask writer and/or requirements of the IC fab 1640. In FIG. 27, the mask data preparation 1632 and mask fabrication 1634 are illustrated as separate elements. In some embodiments, the mask data preparation 1632 and mask fabrication 1634 can be collectively referred to as mask data preparation.

In some embodiments, the mask data preparation 1632 includes optical proximity correction (OPC) which uses lithography enhancement techniques to compensate for image errors, such as those that can arise from diffraction, interference, other process effects and the like. OPC adjusts the IC design layout 1622. In some embodiments, the mask data preparation 1632 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 1632 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 1634, which may undo part of the modifications performed by OPC in order to meet mask creation rules.

In some embodiments, the mask data preparation 1632 includes lithography process checking (LPC) that simulates processing that will be implemented by the IC fab 1640 to fabricate the IC device 1660. LPC simulates this processing based on the IC design layout 1622 to create a simulated manufactured device, such as the IC device 1660. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 1622.

It should be understood that the above description of the mask data preparation 1632 has been simplified for the purposes of clarity. In some embodiments, the mask data preparation 1632 includes additional features such as a logic operation (LOP) to modify the IC design layout according to manufacturing rules. Additionally, the processes applied to the IC design layout 1622 during the mask data preparation 1632 may be executed in a variety of different orders.

After the mask data preparation 1632 and during mask fabrication 1634, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 1634 is used in a variety of processes. For example, such a mask(s) is used in an ion implantation process to form various doped regions in the semiconductor wafer (e.g., the n-type doped regions 14 and the p-type doped region 16), in an etching process to form various etching regions in the semiconductor wafer, and/or in other suitable processes.

The IC fab 1640 is an IC fabrication entity that includes one or more manufacturing facilities for the fabrication of a variety of different IC products. In some embodiments, the IC fab 1640 is a semiconductor foundry. For example, there may be a first manufacturing facility for the front-end fabrication of a plurality of IC products (e.g., the epitaxial source/drain features 40A-40C, the gate structures 30A-30C), while a second manufacturing facility may provide the middle end fabrication for the interconnection of the IC products (e.g., the vias 50-56, contact features, gate contacts, etc.) and a third manufacturing facility may provide the back end fabrication for the interconnection and packaging of the IC products (e.g., frontside metallization layers, backside metallization layers, etc.), and a fourth manufacturing facility may provide other services for the foundry entity.

The IC fab 1640 uses the mask (or masks) fabricated by the mask house 1630 to fabricate the IC device 1660. Thus, the IC fab 1640 at least indirectly uses the IC design layout 1622 to fabricate the IC device 1660. In some embodiments, a semiconductor wafer 1642 is fabricated by the IC fab 1640 using the mask (or masks) to form the IC device 1660. The semiconductor wafer 1642 includes a silicon substrate or other proper substrate having material layers formed thereon. Semiconductor wafer further includes one or more of various doped regions, dielectric features, multilevel interconnects, and the like (formed at subsequent manufacturing steps).

The IC manufacturing system 1600 is shown as having the design house 1620, mask house 1630, and IC fab 1640 as separate components or entities. However, it should be understood that one or more of the design house 1620, mask house 1630, and IC fab 1640 are part of the same component or entity.

In one aspect of the present disclosure, a memory device includes a first memory array disposed over a substrate, a second memory array disposed over the substrate and separated from the first memory array along a first direction, and a strap cell defined in the substrate and interposed between the first memory array and the second memory array. The strap cell includes a first boundary abutting the first memory array, a second boundary abutting the second memory array, a p-type well strap interposed between the first boundary and the second boundary along the first direction, and an n-type well strap spaced from the p-type well strap along the second direction. The first boundary and the second boundary extending along a second direction perpendicular to the first direction. The p-type well strap is coupled to a first power supply voltage, and the n-type well strap is coupled to a second power supply voltage.

In another aspect of the present disclosure, a memory device includes a first bank of memory arrays disposed over a substrate. The memory device includes a second bank of memory arrays disposed over the substrate and separated from the first bank along a first direction. The memory device includes a first strap cell interposed between the first bank and the second bank, where the first strap cell directly adjoins the first bank and the second bank. The memory device includes a second strap cell adjoining the first bank opposite the first strap cell along the first direction. The memory device includes a third strap cell adjoining the second bank opposite the second strap cell along the first direction. The first strap cell has a first width along the first direction. The second strap cell and the third strap cell each have a second width along the first direction. The second width is different from the first width.

In yet another aspect of the present disclosure, a memory device includes a first memory device over a substrate and a second memory device over the substrate, a middle edge cell abutting each of the first memory device and the second memory device, an upper edge cell abutting the first memory device opposite the middle edge cell, and a lower edge cell abutting the second memory device opposite the middle edge cell. The first memory device includes a first memory array and a first strap cell abutting the first memory array, where the first strap cell and the first memory array are arranged along a first direction. The first strap cell includes a first well strap electrically coupled to a first power supply voltage and a second well strap electrically coupled to a second power supply voltage. The second memory device is aligned with the first memory device along a second direction perpendicular to the first direction. The second memory device includes a second memory array aligned with the first memory array along the second direction. The middle edge cell has a first height along the second direction, the upper edge cell has a second height along the second direction, and the lower edge cell has a third height along the second direction, where the first height is less than a sum of the second height and the third height.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a first memory array disposed over a substrate;
a second memory array disposed over the substrate and separated from the first memory array along a first direction; and
a strap cell defined in the substrate and interposed between the first memory array and the second memory array, the strap cell including:
a first boundary abutting the first memory array,
a second boundary abutting the second memory array, the first boundary and the second boundary extending along a second direction perpendicular to the first direction,
a p-type well strap interposed between the first boundary and the second boundary along the first direction, and
an n-type well strap spaced from the p-type well strap along the second direction, wherein:
the p-type well strap is coupled to a first power supply voltage, and
the n-type well strap is coupled to a second power supply voltage.

2. The memory device of claim 1, wherein the first power supply voltage is electrical ground, and wherein the second power supply voltage is a positive power supply voltage.

3. The memory device of claim 1, wherein the strap cell further includes:
a n-type transistor disposed adjacent to the p-type well strap along the first direction, the n-type transistor including a first gate terminal, and
a p-type transistor disposed adjacent to the n-type well strap along the first direction, the p-type transistor including a second gate terminal, the first gate terminal and the second gate terminal each coupled to the first power supply voltage and the second power supply voltage, respectively.

4. The memory device of claim 1, further comprising:
a p-type doped region defined in the substrate and extending across the first memory array, the strap cell, and the second memory array along the first direction, the p-type well strap disposed in the p-type doped region; and
an n-type doped region defined in the substrate and extending across the first memory array, the strap cell, and the second memory array along the first direction, the n-type well strap disposed the n-type doped region.

5. The memory device of claim 4, wherein the strap cell further includes:
a first via coupling the p-type well strap to the first power supply voltage, and
a second via coupling the n-type well strap to the second power supply voltage.

6. The memory device of claim 1, further comprising:
a first peripheral circuit configured to control the first memory array; and
a second peripheral circuit configured to control the second memory array, the first peripheral circuit and the second peripheral circuit disposed on opposite sides of the strap cell.

7. A memory device, comprising:
a first bank of memory arrays disposed over a substrate;
a second bank of memory arrays disposed over the substrate and separated from the first bank along a first direction;
a first strap cell interposed between the first bank and the second bank, the first strap cell directly adjoining the first bank and the second bank;
a second strap cell adjoining the first bank opposite the first strap cell along the first direction; and
a third strap cell adjoining the second bank opposite the second strap cell along the first direction, wherein:
the first strap cell has a first width along the first direction,
the second strap cell and the third strap cell each have a second width along the first direction, and
the second width is different from the first width.

8. The memory device of claim 7, wherein:
the second width is less than the first width, and
the first strap cell includes a p-type well strap and an n-type well strap spaced from the p-type well strap along a second direction perpendicular to the first direction, wherein:
the p-type well strap is coupled to a first power supply voltage, and
the n-type well strap is coupled to a second power supply voltage.

9. The memory device of claim 8, wherein the second strap cell and the third strap cell are electrically isolated from each of the first power supply voltage and the second power supply voltage.

10. The memory device of claim 7, wherein:
the second width is greater than the first width,
the second strap cell includes a first p-type well strap and a first n-type well strap spaced from the first p-type well strap along a second direction perpendicular to the first direction, wherein:
the first p-type well strap is coupled to a first power supply voltage, and
the first n-type well strap is coupled to a second power supply voltage; and
the third strap cell includes a second p-type well strap and a second n-type well strap spaced from the second p-type well strap along the second direction, wherein:
the second p-type well strap is coupled to the first power supply voltage, and
the second n-type well strap is coupled to the second power supply voltage.

11. The memory device of claim 10, wherein the first strap cell is electrically isolated from each of the first power supply voltage and the second power supply voltage.

12. The memory device of claim 7, wherein the first bank includes a first number of memory arrays arranged along a second direction perpendicular to the first direction, and wherein the second bank includes a second number of memory arrays arranged along the second direction, the first number and the second number each being greater than or equal to 1.

13. The memory device of claim 7, further comprising:
a first peripheral circuit configured to control the first bank; and
a second peripheral circuit configured to control the second bank, the first peripheral circuit and the second peripheral circuit disposed on opposite sides of the first strap cell.

14. The memory device of claim 7, further comprising a transition cell aligned with the first strap cell along a second direction perpendicular to the first direction, the transition cell having a fourth width along the first direction, wherein the fourth width is the same as the first width.

15. A semiconductor structure, comprising:
a first memory device over a substrate, the first memory device including:
a first memory array, and
a first strap cell abutting the first memory array, the first strap cell and the first memory array arranged along a first direction, the first strap cell including a first well strap electrically coupled to a first power supply voltage and a second well strap electrically coupled to a second power supply voltage;
a second memory device over the substrate and aligned with the first memory device along a second direction perpendicular to the first direction, the second memory device including a second memory array aligned with the first memory array along the second direction;
a middle edge cell abutting each of the first memory device and the second memory device, the middle edge cell having a first height along the second direction,
an upper edge cell abutting the first memory device opposite the middle edge cell, the upper edge cell having a second height along the second direction; and
a lower edge cell abutting the second memory device opposite the middle edge cell, the lower edge cell having a third height along the second direction, wherein the first height is less than a sum of the second height and the third height.

16. The semiconductor structure of claim 15, wherein the second memory device further includes a second strap cell adjacent the second memory array along the first direction and aligned with the first strap cell along the second direction, the second strap cell including a third well strap electrically coupled to the first power supply voltage and a fourth well strap electrically coupled to the second power supply voltage.

17. The semiconductor structure of claim 16, wherein the middle edge cell abuts one of the first memory array and the second memory array.

18. The semiconductor structure of claim 17, wherein the middle edge cell abuts both the first memory array and the second memory array.

19. The semiconductor structure of claim 15, wherein:
the first memory device further comprises a second strap cell abutting the first memory array, the second strap cell opposite the first strap cell along the first direction,
the first strap cell has a first width along the first direction,
the second strap cell has a second width along the first direction, the second width different from the first width, and
the second strap cell is electrically isolated from the first power supply voltage and the second power supply voltage.

20. The semiconductor structure of claim 19, further comprising:
a third memory array adjacent the first memory array along the first direction, the third memory array abutting the first strap cell; and
a third strap cell abutting the third memory array along the first direction, the third strap cell opposite the first strap cell along the first direction, wherein:
the third strap cell has a third width along the first direction, the third width the same as the second width, and
the third strap cell is electrically isolated from the first power supply voltage and the second power supply voltage.
